(19) United States
(12) Patent Application Publication
(10) Pub. No.: US 2023/0395697 A1
(43) Pub. Date: Dec. 7, 2023

(54) REMOVAL OF UPPER CHANNEL BODIES IN STACKED GATE-ALL-AROUND (GAA) DEVICE STRUCTURES

(71) Applicant: Intel Corporation, Santa Clara, CA (US)

(72) Inventors: Nicole K. Thomas, Portland, OR (US); Munzarin F. Qayyum, Hillsboro, OR (US); Marko Radosavljevic, Portland, OR (US); Cheng-Ying Huang, Hillsboro, OR (US); Willy Rachmady, Beaverton, OR (US); Rohit Galatage, Hillsboro, OR (US); Jami A. Wiedemer, Scappoose, OR (US); David Bennett, Portland, OR (US); Dincer Unluer, Hillsboro, OR (US); Venkata Aditya Addepalli, Portland, OR (US)

(73) Assignee: Intel Corporation, Santa Clara, CA (US)

(21) Appl. No.: 17/831,800

(22) Filed: Jun. 3, 2022

(51) Int. Cl. H01L 29/66; H01L 29/423; H01L 29/786; H01L 29/06; H01L 21/8238

(52) U.S. Cl. CPC H01L 29/66545; H01L 29/42392; H01L 29/78696; H01L 29/0669; H01L 21/823807

(57) ABSTRACT

A semiconductor structure includes a second device stacked over a first device. In an example, the first device includes (i) a first source region, (ii) a first drain region, (iii) a body including a semiconductor material extending laterally from the first source region to the first drain region, and (iv) a first gate structure at least in part wrapped around the body. The body can be, for instance, a nanoribbon, nanosheet, or nanowire. In an example, the second device comprises (i) a second source region, (ii) a second drain region, and (iii) a second gate structure at least in part laterally between the second source region and the second drain region. In an example, the second device lacks a continuous body extending laterally from the second source region to the second drain region.

### FIELD OF THE DISCLOSURE

The present disclosure relates to integrated circuits, and more particularly, to stacked semiconductor devices.

### BACKGROUND

Integrated circuitry continues to scale to smaller feature dimensions and higher transistor densities. A more recent development with respect to increasing transistor density is generally referred to as three-dimensional (3D) integration, which expands transistor density by exploiting the z-dimension (build upwards rather than laterally outwards in the x- and y-dimensions). For example, multiple transistors are stacked in a vertical direction.

### BRIEF DESCRIPTION OF THE DRAWINGS

FIGS. 1A-1C illustrate various views of an example semiconductor structure comprising a stacked device configuration including (i) lower devices each having a continuous channel structure, and (ii) upper devices each lacking a continuous channel structure, wherein an interface is present between a gate structure of the lower devices and a gate structure of the upper devices, in accordance with an embodiment of the present disclosure.

FIG. 1D illustrates a perspective view of the example semiconductor structure of FIGS. 1A-1C that is adjacent to another semiconductor structure having a stacked device configuration including (i) lower devices each having a continuous channel structure, and (ii) upper devices also each having a continuous channel structure, in accordance with an embodiment of the present disclosure.

FIGS. 2A and 2B illustrate various cross-sectional views of a semiconductor structure comprising a stacked device configuration including (i) lower devices each having a continuous channel structure, and (ii) upper devices each lacking a continuous channel structure, wherein a lower gate electrode of a lower device and an upper gate electrode of a upper device form a continuous common gate electrode, without any interface between the lower and upper gate structures, in accordance with an embodiment of the present disclosure.

FIGS. 3A and 3B illustrate various cross-sectional views of a semiconductor structure comprising a stacked device configuration including (i) lower devices each having a continuous channel structure, and (ii) upper devices each lacking a continuous channel structure, wherein a lower gate electrode of a lower device and an upper gate electrode of a corresponding upper device are separated by a non-conductive isolation region, in accordance with an embodiment of the present disclosure.

FIG. 4 illustrates a flowchart depicting a method of forming the example nanoribbon semiconductor structure of FIGS. 1A-1C, in accordance with an embodiment of the present disclosure.

FIGS. 5A1, 5A2, 5B1, 5B2, 5C1, 5C2, 5D1, 5D2, 5E1, 5E2, 5F1, 5F2, 5G1, and 5G2 collectively illustrate cross-sectional views of an example semiconductor structure (e.g., the semiconductor structure of FIGS. 1A-1C) in various stages of processing, in accordance with an embodiment of the present disclosure.

FIG. 6 illustrates a flowchart depicting a method of forming the example nanoribbon semiconductor structure of FIGS. 2A-2B, in accordance with an embodiment of the present disclosure.

FIGS. 7A, 7B, 7C1, 7C2, 7D1, 7D2, 7E1, 7E2, 7F1, and 7F2 collectively illustrate cross-sectional views of an example semiconductor structure (e.g., the semiconductor structure of FIGS. 2A-2B) in various stages of processing, in accordance with an embodiment of the present disclosure.

FIG. 8 illustrates a computing system implemented with integrated circuit structures and/or transistor devices formed using the techniques disclosed herein, in accordance with some embodiments of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles (e.g., curved or tapered sidewalls and round corners), and some features may have surface topography or otherwise be non-smooth, given real-world limitations of fabrication processes. Further still, some of the features in the drawings may include a patterned and/or shaded fill, which is merely provided to assist in visually identifying the different features. In short, the figures are provided merely to show example structures.

### DETAILED DESCRIPTION

Integrated circuit structures including vertically stacked semiconductor devices are discussed herein, wherein an upper device above a lower device has its channel regions removed. The channel regions removed from the upper device may include, for example, fin portion, or one or more nanoribbons, nanowires, nanosheets, or any other such semiconductor bodies around which a gate structure can at least partially wrap. In one example embodiment, a semiconductor structure includes a second device stacked over a first device. In an example, the first device includes (i) a first source region, (ii) a first drain region, (iii) a body including a semiconductor material extending laterally from the first source region to the first drain region, and (iv) a first gate structure at least in part wrapped around the body. The body can be, for instance, a fin, nanoribbon, nanosheet, or nanowire. In an example, the second device comprises (i) a second source region, (ii) a second drain region, and (iii) a second gate structure at least in part laterally between the second source region and the second drain region. In an example, the second device lacks a body of semiconductor material extending laterally from the second source region to the second drain region. In some such cases, an interface between the first and second gate structures includes one or more bumps that can be seen in cross-sectional profile. The bumps correspond to topology on a top surface of the first (lower) gate structure.

In another example embodiment, an integrated circuit structure comprises a source region, a drain region, and a gate electrode at least in part laterally between the source region and the drain region. A first spacer is laterally between the gate electrode and the source region, and a second spacer is laterally between the gate electrode and the drain region. In an example, a first body comprising semiconductor material is at least in part wrapped by the first spacer and is contact with the source region. In an example, a second body comprising semiconductor material is at least in part wrapped by the second spacer and is contact with the drain region. In an example, the first body and the second body are coplanar and separated by the gate electrode. In an example, the first body and the second body are two end sections of a nanoribbon, wherein a middle section between the two end sections of the nanoribbon has been depopulated, e.g., removed.

In yet another example embodiment, a method comprises forming a second device stacked vertically over a first device. In an example, the first device includes a first body extending laterally between and in contact with a first source region and a first drain region, and the second device includes a second body extending laterally between and in contact with a second source region and a second drain region. In an example, the second body includes (i) a first end section wrapped at least in part by a first spacer, (ii) a second end section wrapped at least in part by a second spacer, and (iii) a central section laterally between the first and second end sections. In an example, the method further includes removing the central section of the second body, without removing the first and second end sections of the second body and without removing the first body. The method may further include forming a gate structure between the first and second end sections of the second body.

### General Overview

A stacked device architecture can in include an upper device stacked above a lower device. In some cases, the upper and lower devices can be arranged in a complementary metal oxide semiconductor (CMOS) architecture. For instance, the upper device can be one of an n-channel metal-oxide semiconductor (NMOS) device or a p-channel metal-oxide semiconductor (PMOS) device, and the lower device can be the other of the NMOS or the PMOS device.

In an example, it may be desirable to make the upper device a dummy or non-operational device, such that only the lower device is operational. Accordingly, techniques are provided herein to depopulate or otherwise remove the channel regions of the upper device, without removing channel regions of the lower device. For example, individual ones of the stacked devices are gate-all-around (GAA) devices, in which a gate structure wraps around a channel region that extends laterally between a corresponding source region and a gate region. An example of the channel regions in a GAA device includes nanoribbons. As will be appreciated in light of this disclosure, reference to nanoribbons as channel regions is also intended to include other gate-all-around channel regions, such as nanowires, nanosheets, and other such semiconductor bodies around which a gate structure can wrap. To this end, the use of a specific channel region configuration (e.g., nanoribbon) is not intended to limit the present description to that specific channel configuration. Rather, the techniques provided herein can benefit any number of channel configurations, whether those bodies be nanowires, nanoribbons, nanosheets or some other body around which a gate structure can at least partially wrap (such as the semiconductor bodies of a forksheet device or a fin-based device).

In one embodiment, nanoribbons of the upper device in a stacked GAA device structure are at least in part removed, without removing the nanoribbons of the lower device of the stacked device structure. For example, prior to removing the nanoribbons, one or more nanoribbons of the upper device extend laterally from an upper source region to an upper drain region of the upper device, and one or more nanoribbons of the lower device extend laterally from a lower source region to a lower drain region of the lower device. In the stacked device architecture, the upper device is stacked above the lower device. For example, the upper source region is above the lower source region, and is separated from the lower source region by a non-conductive isolation region that is between the upper and lower source regions. Similarly, the upper drain region is above the lower drain region, and is separated from the lower drain region by another non-conductive isolation region that is between the upper and lower drain regions. In still other embodiments, the upper and lower source regions and/or the upper and lower drain regions may be connected to one another. A lower gate structure of the lower device wraps around the nanoribbons of the lower device. For example, the lower gate structure comprises a lower gate electrode wrapping around the nanoribbons of the lower device, and gate dielectric (and optionally work function metal) between the lower gate electrode and the nanoribbons of the lower device. A first inner gate spacer separates the gate electrodes of the upper and lower devices from the upper and lower source regions, and a second inner gate spacer separates the gate electrodes of the upper and lower devices from the upper and lower drain regions. A nanoribbon of the lower device has (i) a first end section wrapped at least in part by the first inner gate spacer, (ii) a second end section wrapped at least in part by the second inner gate spacer, and (iii) a middle or central section between the two end sections, wherein the lower gate structure wraps around the central section.

In one embodiment, individual nanoribbons of the upper device are removed. Note that in an example, an entirety of the nanoribbons of the upper device may not be removed. For example, end sections of the nanoribbons of the upper devices, which are wrapped by the inner gate spacers, are not removed according to some embodiments. However, the central section of the nanoribbons of the upper device are removed. Accordingly, in the upper device, the upper gate structure (e.g., comprising an upper electrode and gate dielectric) does not wrap around any central section of any nanoribbon. The end sections of a nanoribbon of the upper device are discontinuous, e.g., not conjoined by a corresponding central section of the nanoribbon. In an example, the gate dielectric in the upper device is on sidewalls of the inner gate spacers and separates the two end sections of individual nanoribbons of the upper device from the upper gate electrode.

In an example, an interface (e.g., a seam or a grain boundary) is between the upper gate structure and the lower gate structure. In an example, the interface is non-planar, e.g., has a bump or an elongated portion above the nanoribbons of the lower device, where the bump or the elongated portion is elongated away from the nanoribbon of the lower device, as will be discussed herein in turn. In another example, no such interface is between the upper gate structure and the lower gate structure, and the upper and lower gate electrodes form a continuous and monolithic common gate electrode for both devices. In yet another example, the upper gate structure and the lower gate structure are separated by a non-conductive isolation region between the upper and lower gate structures.

In an example, a vertical stack comprises an upper device and a lower device, and several such stacks each having an upper device and a corresponding lower device can be arranged proximally. For example, a first stack includes a first upper device above a first lower device, and a second stack includes a second upper device above a second lower device, where the first and second stacks are arranged in a horizontal or side-by-side configuration. In an example, one or more of the upper devices, but not necessarily all, lacks corresponding central sections of the nanoribbons. In an example, two lower devices can share a common lower gate structure, and two upper devices can share a common upper gate structure. In another example, a gate cut structure can separate the lower gate electrode of the two adjacent lower devices, and/or a gate cut structure can separate the upper gate electrode of the two adjacent upper devices. Note that an upper channel region that has been depopulated can be laterally adjacent to an upper channel region that has not been depopulated.

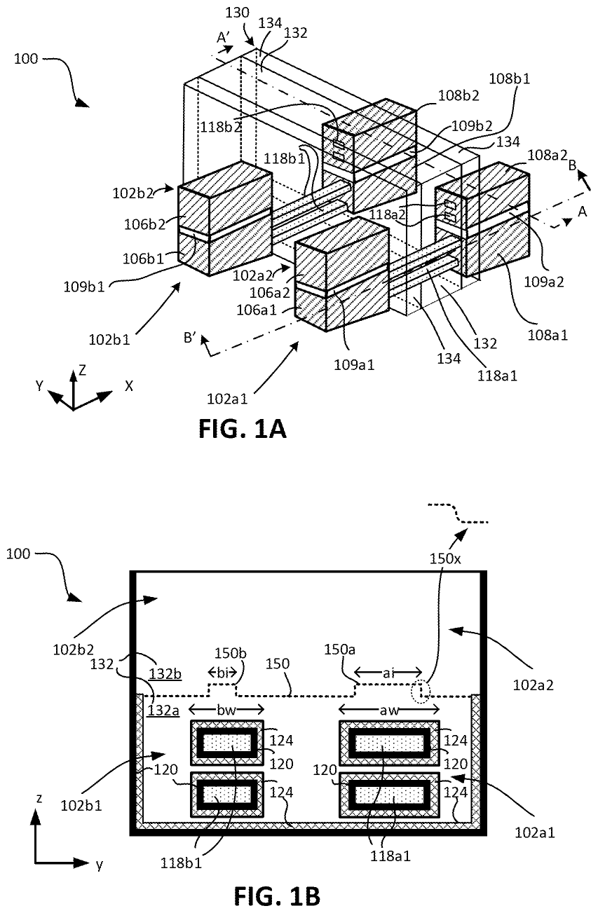

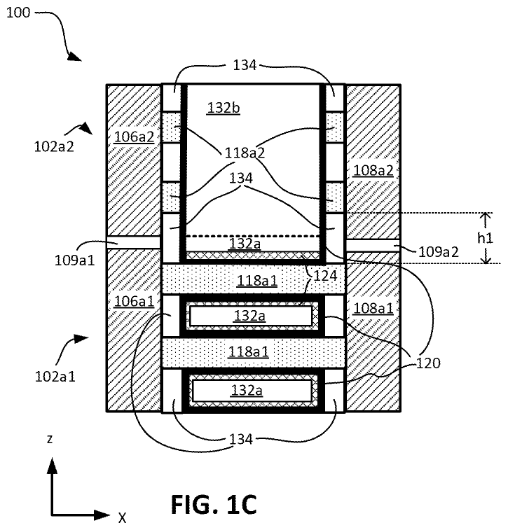

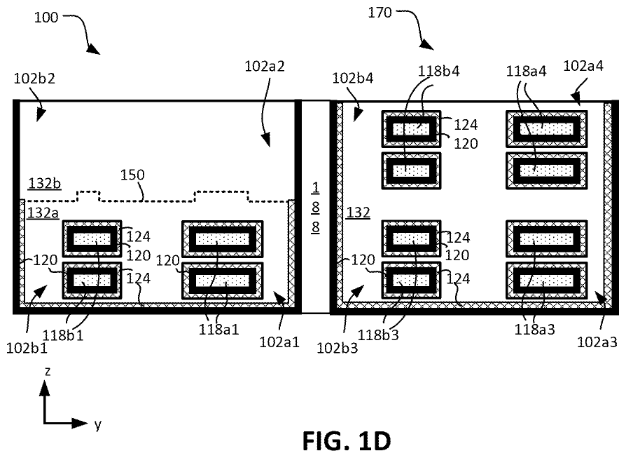

In one example method to form the stacked devices (e.g., with nanoribbons of the upper device at least in part removed), the nanoribbons of the upper and lower devices are formed, and source and drain regions of the upper and lower devices are formed on two ends of the nanoribbons. Subsequently, the nanoribbons of the upper and lower devices are released, and gate dielectric and work function metal are deposited around the nanoribbons. Subsequently, a gate electrode is formed, the gate electrode wrapping around nanoribbons of both upper and lower devices. The gate electrode is then recessed (e.g., using an appropriate etching process) from the top, such that the nanoribbons of the upper device is exposed through the recessed gate electrode, while the recessed gate electrode continues to wrap around the nanoribbons of the lower device. Thus, as the gate electrode is now wrapping around the nanoribbons of only the lower device, the gate electrode is also referred to as lower gate electrode of the lower device. The gate dielectric and the work function metal around the nanoribbons of the upper device are then removed, and then the nanoribbons of the upper device are removed, e.g., using one or more selective etch processes. For example, the etch processes remove the gate dielectric and the work function metal, and then the nanoribbons, without substantially impacting the lower gate electrode protecting the nanoribbons of the lower device from being etched. Thus, the lower gate electrode acts as an etch stop layer during the etch processes. It may be noted that the etch processes remove the exposed central sections of the nanoribbons of the upper device, while the end sections of the nanoribbons of the upper device are protected by the inner gate spacers (e.g., see FIG. 1C herein in turn) and are not removed. Subsequently, an upper gate electrode is formed above the lower gate electrode. Depending on the process, the upper gate structure may include a gate dielectric, work function material, and gate fill material, which may be helpful to keep a common process despite some upper channel regions being depopulated as variously described herein. In some such cases, as the lower gate electrode and the upper gate electrode are formed using two different gate electrode formation process, an interface is formed between the upper and lower gate structures, as discussed herein in further detail in turn.

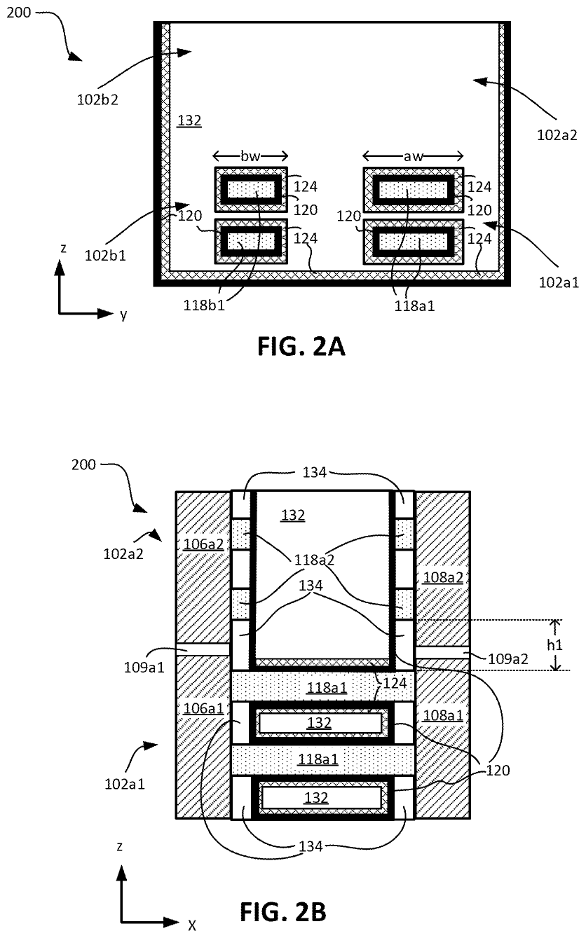

In another example method to form the stacked devices (e.g., with nanoribbons of the upper device at least in part removed), the nanoribbons of the upper and lower devices are formed, and source and drain regions of the upper and lower devices are formed on two ends of the nanoribbons. Subsequently, the nanoribbons of the upper and lower devices are released. A layer of sacrificial material is deposited, such that the sacrificial material wraps around the nanoribbons of both upper and lower devices. The sacrificial material is then recessed (e.g., using an appropriate etching process) from the top, such that the nanoribbons of the upper device is exposed through the recessed sacrificial material, while the recessed sacrificial material continues to wrap around the nanoribbons of the lower device. The nanoribbons of the upper devices are then at least partially etched using a selective etch process. For example, the etch process removes the exposed central section of the nanoribbons of the upper device, without substantially impacting the sacrificial material protecting the nanoribbons of the lower device from being etched. Thus, the sacrificial material acts as an etch stop layer during the etch process. It may be noted that the etch process removes the central sections of the nanoribbons of the upper device, while the end sections of the nanoribbons of the upper device are protected by the inner gate spacers (e.g., see FIG. 2B herein in turn) and are not removed. Subsequently, the sacrificial material is removed (e.g., using an isotropic etch process), and gate dielectric and work function metal are deposited on the nanoribbons. Finally, the gate electrode of both upper and lower devices is formed using a single gate electrode formation process, and hence, no interface is now present between the upper and lower gate structures. For example, the upper and lower gate electrodes form a continuous and monolithic common gate electrode for both the devices. Again, note that an upper channel region that has been depopulated can be laterally adjacent to an upper channel region that has not been depopulated.

The use of “group IV semiconductor material” (or “group IV material” or generally, “IV”) herein includes at least one group IV element (e.g., silicon, germanium, carbon, tin), such as silicon (Si), germanium (Ge), silicon-germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), gallium nitride (GaN), and so forth. Note that group III may also be known as the boron group or IUPAC group 13, group IV may also be known as the carbon group or IUPAC group 14, and group V may also be known as the nitrogen family or IUPAC group 15, for example.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may indicate a vertically stacked device structure that has (i) a lower device having a channel structure, and (ii) an upper device above the lower device, where the upper device lacks a complete channel structure (e.g., such as the case where one or more nanoribbons have been removed) between source and drain regions of the upper device. Such tools may also indicate the upper device having, for example, a first end section of a nanoribbon of the upper device being at least partially wrapped around by a first inner gate spacer, and a second end section of a nanoribbon of the upper device being at least partially wrapped around by a second inner gate spacer, wherein a gate electrode of the upper device is laterally between the first and second end sections, such that the first and second end sections are discontinuous and not conjoined. Such tools may further be used to detect an upper channel region that has been depopulated and that is laterally adjacent to an upper channel region that has not been depopulated. Numerous configurations and variations will be apparent in light of this disclosure.

### Architecture and Methodology

FIG. 1A illustrates a perspective view of an example semiconductor structure 100 (also referred to herein as “structure 100”), FIG. 1B illustrates a cross-sectional view of the semiconductor structure 100, and FIG. 1C illustrates another cross-sectional view of the semiconductor structure 100, where the semiconductor structure 100 comprises a stacked device configuration including (i) lower devices 102a1 and 102b1 each having a continuous channel structure, and (ii) upper devices 102a2 and 102b2 each lacking a continuous channel structure, wherein an interface is present between a gate structure of the lower devices and a gate structure of the upper devices, in accordance with an embodiment of the present disclosure.

The cross-sectional view of FIG. 1B is along line A-A′ of the perspective view of FIG. 1A. That is, the cross-sectional view of FIG. 1B is along a gate electrode 132 of the structure 100, and this view is also referred to as “gate-cut” view of the structure 100. Thus, the cross-sectional view of FIG. 1B is along a cross-section of nanoribbons 118 of the various devices 102a1, 102b1, and the cross-section of the nanoribbons 118 of the devices 102a1, 102b1 are visible in FIG. 1B.

The cross-sectional view of FIG. 1C is along line B-B′ of FIG. 1A. Thus, in the cross-sectional view of FIG. 1C, only the right-most GAA devices 102a1, 102a2 are visible. Also, the cross-sectional view of FIG. 1C is along the length of nanoribbons 118a1 of the device 102a1, and entire length of nanoribbons 118a1 of the device 102a1 are visible in FIG. 1C. Also visible in FIG. 1C is the device 102a2, and the partial and discontinuous nanoribbons 118a2 of the device 102a2. Note that the devices 102b1 and 102b2 are not visible in the cross-sectional view of FIG. 1C.

In an example, the stacked device configuration of the structure 100 includes upper devices and lower devices, formed on the same fin structure. For example, the upper device 102a2 is stacked above the lower device 102a1, and the upper device 102b2 is stacked above the lower device 102b1. Thus, two pairs of stacked devices are illustrated in FIGS. 1A and 1B, although the structure 100 can include any other appropriate number of such stacked devices, such as one, three, or higher number of pairs of such stacked devices.

The semiconductor bodies included in the channel regions of the lower devices can vary in form, but in this example embodiment are in the form of nanoribbons 118a1 for the lower device 102a1 and nanoribbons 118b1 for the lower device 102b1. Thus, the devices 102a1 and 102b1 are nanoribbon transistor devices, although the devices can be any other type of GAA devices. As will be further appreciated in light of this disclosure, reference to nanoribbons is also intended to include other channel regions, such as nanowires, nanosheets, forksheets, and other such semiconductor bodies around which a gate structure can at least partially wrap. To this end, the use of a specific channel region configuration (e.g., nanoribbon) is not intended to limit the present description to that specific channel configuration.

Note that the upper devices 102a2 and 102b2 are dummy devices, in the sense that the devices 102a2 and 102b2 lack a continuous body or channel region. For example, each nanoribbon 118a2 of the device 102a2 comprises two end sections, but lacks a central section that would have conjoined the two end sections of the nanoribbon 118a2. A first and second end section of each of the nanoribbons 118a2 of the dummy device 102a2 are visible in FIG. 1C, and only the first end section of each of the nanoribbons 118a2 of the dummy device 102a2 are visible in FIG. 1A. Thus, the dummy devices 102a2 and 102b2 lack a channel region surrounded by a gate stack, and cannot conduct any current through any channel region—hence, these upper devices 102a2 and 102b2 are referred to herein as dummy devices.

In an example, a lower device (e.g., device 102a1) is complementary to a corresponding upper device (e.g., device 102a2). For example, the lower devices 102a1, 102b1 can be PMOS devices and the upper devices 102a2, 102b2 can be NMOS devices. In another example, the lower devices 102a1, 102b1 can be NMOS devices and the upper devices 102a2, 102b2 can be PMOS devices. Any other combination may also be possible. In one embodiment, in a device stack, the upper device and the corresponding lower device are configured in a Complementary metal-oxide-semiconductor (CMOS) architecture. As discussed, in the example of FIGS. 1A-1C, the upper devices 102a2 and 102b2 are dummy devices, and hence, an operational CMOS architecture may not be achieved in the structure 100.

In one embodiment, a p-channel device has the corresponding nanoribbons doped with n-type dopants (e.g., phosphorous or arsenic), and an n-channel device has the corresponding nanoribbons doped with p-type dopants (e.g., boron). Note that as discussed, nanoribbons of the upper devices are discontinuous, e.g., includes end sections, but lacks a central section between two end sections.

Although in FIGS. 1A-1B the nanoribbons 118a1 (or the nanoribbons 118b1) extend horizontally and are stacked vertically, the present disclosure contemplates nanoribbons in a variety of configurations that include planar nanoribbon transistors, nanoribbons that extend vertically and are stacked horizontally, and other arrangements, as will be appreciated.

With further reference to FIGS. 1A and 1C, the lower device 102a1 includes a source region 106a1 and a drain region 108a1, which are on two opposite sides of a gated channel region. Similarly, the upper device 102a2 includes a source region 106a2 and a drain region 108a2.

According to some embodiments, the source and drain regions 106, 108 are epitaxial regions that are provided using an etch-and-replace process. In other embodiments one or both of the source and drain regions could be, for example, implantation-doped native portions of the semiconductor fins or substrate. Any semiconductor materials suitable for source and drain regions can be used (e.g., group IV and group III-V semiconductor materials). The source and drain regions may include multiple layers such as liners and capping layers to improve contact resistance. In any such cases, the composition and doping of the source and drain regions may be the same or different, depending on the polarity of the transistors. Any semiconductor materials suitable for source and drain regions can be used (e.g., group IV and group III-V semiconductor materials).

As illustrated in FIGS. 1A and 1C, in an example, the source regions 106a1 and 106a2 are separated by a non-conductive isolation region 109a1. Similarly, the drain regions 108a1 and 108a2 are separated by a non-conductive isolation region 109a2. In an example, the isolation region 109a1 prevents the source region 106a1 from contacting the source region 106a2 , and the isolation region 109a2 prevents the drain region 108a1 from contacting the drain region 108a2. For example, the isolation region 109a1 is between and electrically isolates source regions of the lower device 102a1 and the upper device 102a2, and the isolation region 109a2 is between and electrically isolates drain regions of the lower device 102a1 and the upper device 102a2.

Similarly, the lower device 102b1 includes a source region 106b1 and a drain region 108b1 (see FIG. 1A). Similarly, the corresponding upper device 102b2 includes a source region 106b2 and a drain region 108b2. As illustrated in FIG. 1A, in an example, the source regions 106b1 and 106b2 are separated by a non-conductive isolation region 109b1. Similarly, the drain regions 108b1 and 108b2 are separated by a non-conductive isolation region 109b2. In an example, the isolation region 109b1 electrically isolates the source region 106b1 from the source region 106b2, and the isolation region 109b2 electrically isolates the drain region 108b1 from the drain region 108b2.

Although not illustrated in FIGS. 1A-1C, each of the source and drain regions 106, 108 of the various devices 102 comprises a corresponding conductive source or drain contact. For example, the source region 106a2 of the upper device 102a2 may include a source contact that is above the source region 106a2 . Similarly, the source region 106a1 of the lower device 102a1 may include a source contact that is below or on a side of the source region 106a1. Any other appropriate source and drain contact configuration may also be possible. Other source and drain regions may also include similar corresponding source or drain contacts. The conductive source or drain contacts may be any suitably conductive material. In some embodiments, conductive contacts include one or more of the same metal materials as gate electrode, or a different conductive material. In some embodiments, the source and drain contacts may include aluminum or tungsten, although any suitable conductive metal or alloy can be used, such as silver, nickel-platinum, or nickel-aluminum, for example. In some embodiments, one or more of the source and drain contacts may include a resistance reducing metal and a contact plug metal, or just a contact plug, for instance. Example contact resistance reducing metals include, for instance, nickel, aluminum, titanium, gold, gold-germanium, nickel-platinum, nickel aluminum, and/or other such resistance reducing metals or alloys. Example contact plug metals include, for instance, aluminum, copper, nickel, platinum, titanium, or tungsten, or alloys thereof, although any suitably conductive contact metal or alloy may be used. In some embodiments, additional layers may be present in the source and drain contact regions, such as adhesion layers (e.g., titanium nitride) and/or liner or barrier layers (e.g., tantalum nitride), if so desired. In some embodiments, a contact resistance reducing layer may be present between a given source or drain region and its corresponding source or drain contact, such as a relatively highly doped (e.g., with dopant concentrations greater than 1E18, 1E19, 1E20, 1E21, or 1E22 atoms per cubic cm) intervening semiconductor material layer, for example. In some such embodiments, the contact resistance reducing layer may include semiconductor material and/or impurity dopants based on the included material and/or dopant concentration of the corresponding source or drain region, for example.

The devices 102a1, 102a2, 102b1, and 102b2 comprise a corresponding gate structure 130. Note that the gate structure of FIG. 1A is illustrated as being transparent in order to show the geometry of the nanoribbons 118. However, the illustration is not limiting and the materials used to form the gate structure are not necessarily transparent.

For example, referring to FIGS. 1B and 1C, the device 102a1 comprise a gate structure that includes a gate electrode 132a. Note that in the example of FIG. 1B, the gate electrode 132a is common to both the lower devices 102a1 and 102b1. For example, the gate electrode 132a at least in part wraps the nanoribbons 118a1 of the lower device 102a1 (see FIGS. 1B and 1C), and also at least in part wraps the nanoribbons 118b1 of the lower device 102b1 (see FIG. 1B).

In one embodiment, the gate structure includes a gate dielectric 120 (not illustrated in FIG. 1A but illustrated in FIGS. 1B and 1C) that wraps around each of the nanoribbons 118a1 and 118b1 of the devices 102a1 and 102b1, respectively. The gate electrode 132a wraps around the gate dielectric 120. The gate dielectric 120 is, thus, between the gate electrode 132a and the nanoribbons 118a1, 118b1. Note that FIG. 1A does not illustrate the gate dielectric 120, for purposes of illustrative clarity.

In an example, the gate electrode 132a may include any sufficiently conductive material, such as a metal, metal alloy, or doped polysilicon. The gate electrode may include a wide range of materials, such as polysilicon or various suitable metals or metal alloys, such as aluminum (Al), tungsten (W), titanium (Ti), tantalum (Ta), copper (Cu), titanium nitride (TiN), or tantalum nitride (TaN), for example.

The gate dielectric 120 may include a single material layer or multiple stacked material layers. The gate dielectric may include, for example, any suitable oxide (such as silicon dioxide), high-k dielectric material, and/or any other suitable material as will be apparent in light of this disclosure. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. The high-k dielectric material (e.g., hafnium oxide) may be doped with an element to affect the threshold voltage of the given semiconductor device. According to some embodiments, the doping element used in gate dielectric 120 is lanthanum. In some embodiments, the gate dielectric can be annealed to improve its quality when high-k dielectric material is used. In some embodiments, the gate dielectric 120 includes a first layer (e.g., native oxide of nanoribbons 118, such as silicon dioxide or germanium oxide or SiGe-oxide) on the nanoribbons, and a second layer of high-k dielectric (e.g., hafnium oxide) on the first layer.

The combination of gate dielectric 120 and gate electrode 132a and any work function materials generally forms a gate structure for each of the upper devices 102a1, 102b1. In one embodiment, the gate electrode 132a may be interrupted between any adjacent devices 102a1 and 102b1 by a gate cut structure, although not illustrated in the figures. In an example, due to conformal deposition of the gate dielectric 120, the gate dielectric 120 may also be present on inner walls of the inner gate spacers 134, as seen in FIGS. 1B and 1C.

In one embodiment, one or more work function materials 124 may be included around the nanoribbons 118a1 and 118b1, as illustrated in FIGS. 1B and 1C. Note that work function materials 124 are called out separately, but may be considered to be part of the gate electrodes. In this manner, a gate electrode may include multiple layers or components, including one or more work function materials, gate fill material, capping or resistance-reducing material, to name a few examples. In some embodiments, a p-channel device may include a work function metal having titanium, and an n-channel device may include a work function metal having tungsten or aluminum, although other material and combination may also be possible. In some other embodiments, the work function metal may be absent around one or more nanoribbons 118. In still other embodiments, there may be insufficient room for any gate fill material, after deposition of work function material (i.e., a given gate electrode may be all work function material and no fill material).

Referring now to the upper devices 102a2 and 102b2, the upper devices comprise a gate structure that includes a gate electrode 132b. Note that in the example of FIG. 1B, the gate electrode 132b is common to both the upper devices 102a2 and 102b2 (although a gate cut may separate the gate electrode 132b in two isolated sections). Note that as the upper devices 102ba2 and 102b2 do not include any continuous nanoribbons, the gate electrode 132b does not wrap around any nanoribbons. The gate electrodes 132a and 132b, in combination, form a common gate electrode 132 for the devices of the structure 100.

In one embodiment, the gate structure of the upper devices 102a2 and 102b2 also includes a gate dielectric 120 (not illustrated in FIG. 1A but illustrated in FIGS. 1B and 1C). As the upper devices lack do not include continuous nanoribbons, the gate dielectric 120 of the upper devices does not wrap around any corresponding nanoribbon. In an example, the gate dielectric 120 of the upper devices are on sidewalls of inner gate spacers 134 (discussed herein later), see FIGS. 1B and 1C. Thus, the gate dielectric 120 of the upper devices separate the gate electrode 132b of the upper devices from the inner gate spacers 134 and the corresponding source and drain regions.

As illustrated in FIGS. 1A and 1C, inner gate spacers 134 are between the gate electrodes 132a, 132b and the source regions 106, and also between the gate electrodes 132a, 132b and the drain regions 108. Thus, the inner gate spacers 134 are on the source regions 106, and also on the drain regions 108. The inner gate spacers 134 may be appropriate insulator layers (e.g., interlayer dielectric) or dielectric material that electrically isolates the gate electrodes 134 from the source and drain regions. In an example, the inner gate spacers 134 comprises silicon nitride (Si₃N₄) or other suitable non-conductive material, as will be appreciated.

For the lower device 102a1, the corresponding nanoribbons 118a1 extend within and through the inner gate spacers 134, to make contact with the corresponding source region 106a1 and to make contact with the corresponding drain region 108a1, e.g., as illustrated in FIG. 1C. Similarly, for the lower device 102b1, the corresponding nanoribbons 118b1 extend within and through the inner gate spacers 134, to make contact with the corresponding source region 106b1 and to make contact with the corresponding drain region 108b1.

For the upper device 102a2 illustrated in FIG. 1C, the end sections of the nanoribbons 118a2 extend within the inner gate spacers 134, and make contact with the corresponding source region 106a2 and corresponding drain region 108a2. For example, a first end section of a nanoribbon 118a2 extends within a first inner gate spacer and makes contact with the source region 106a2 . and a second end section of the nanoribbon 118a2 extends within a second inner gate spacer and makes contact with the drain region 108a2, see FIG. 1C. Note that the first and second end sections of the nanoribbon 118a2 are coplanar, and there is no central section of the nanoribbon between the two end sections, as illustrated and variously discussed herein.

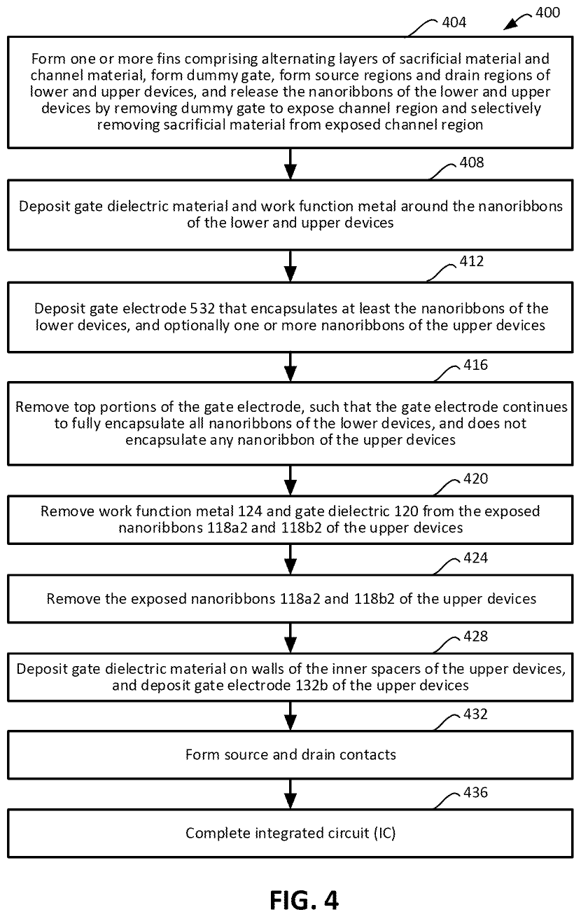

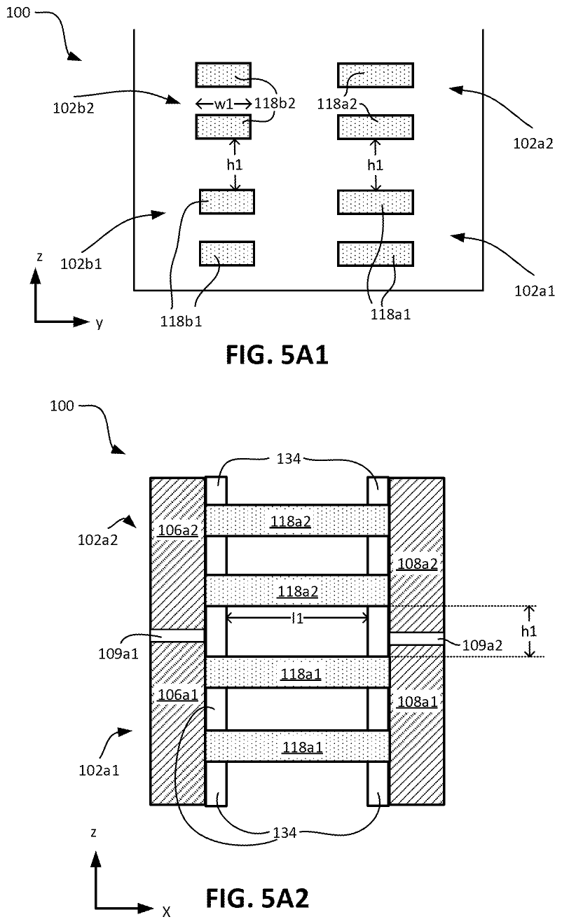

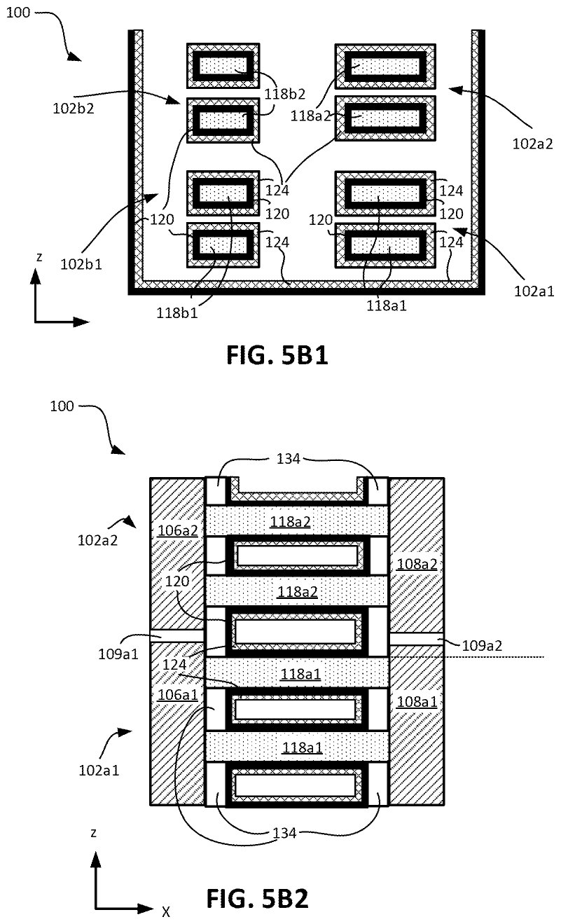

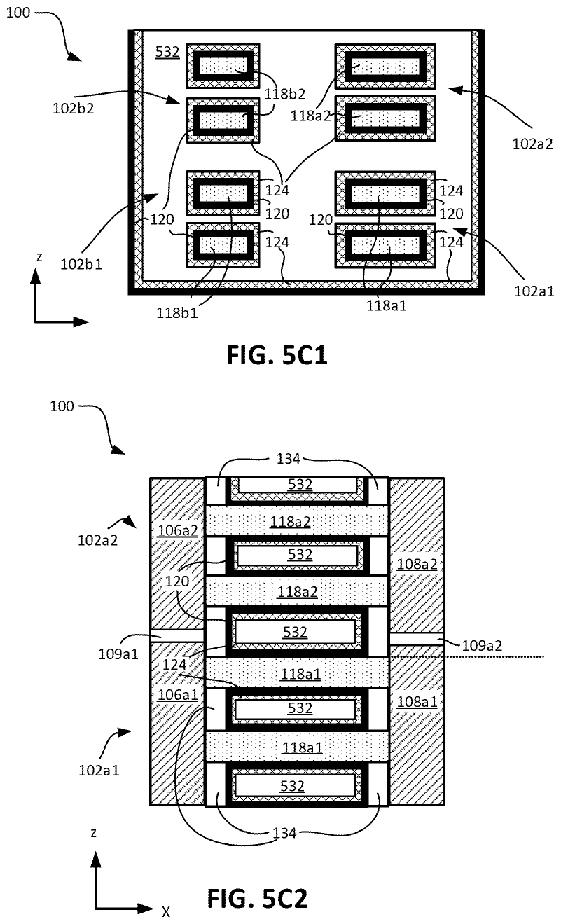

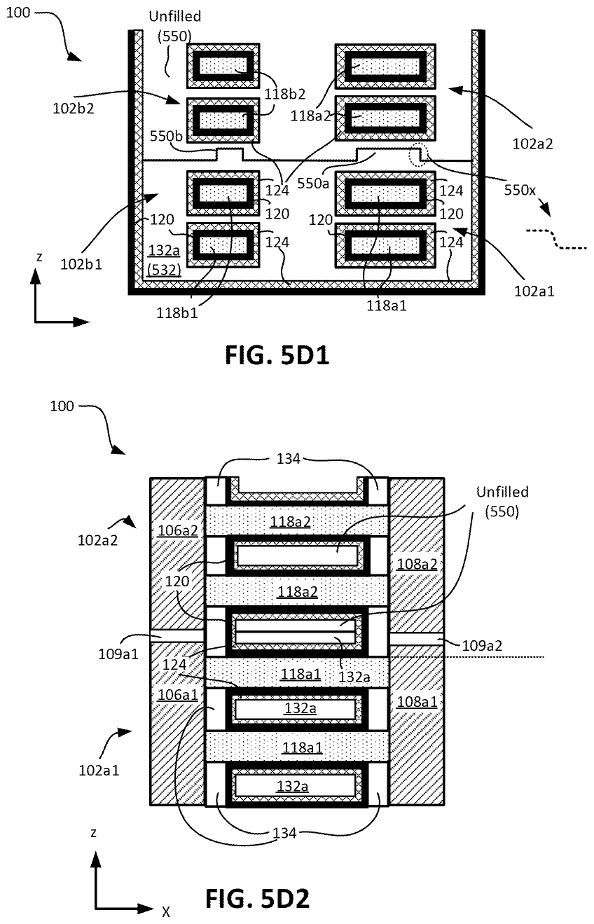

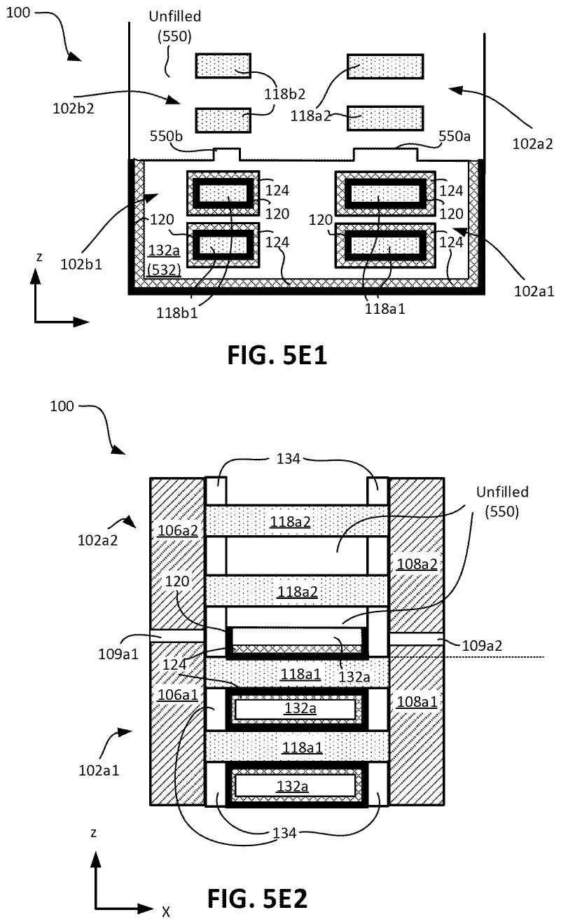

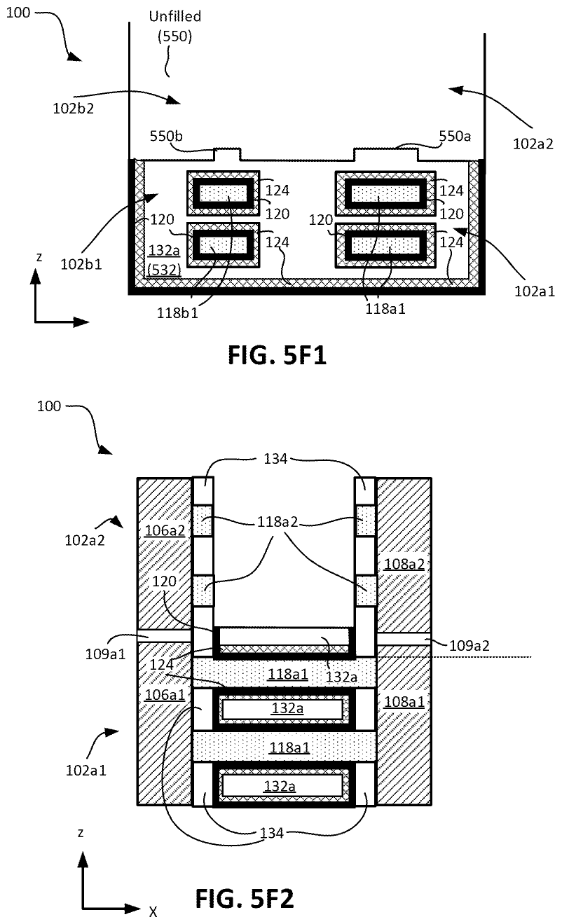

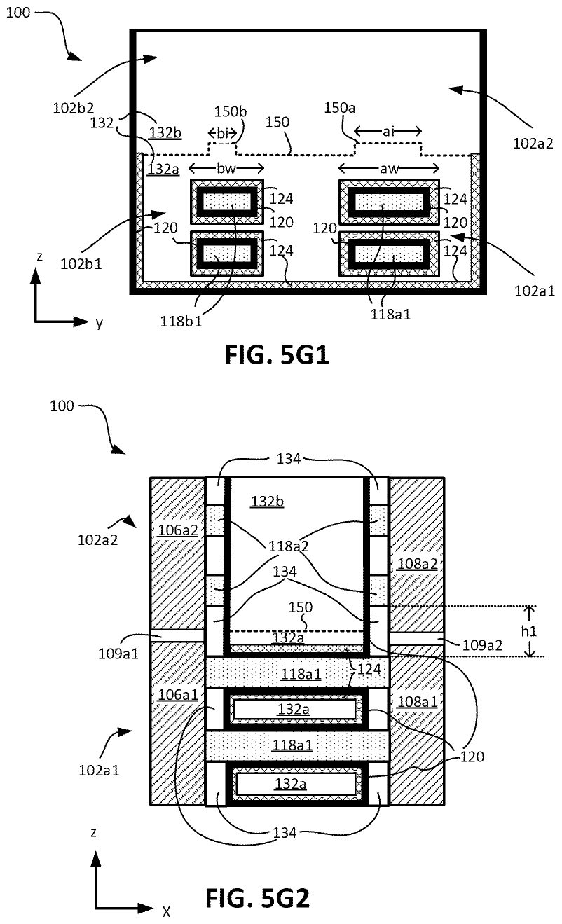

As illustrated in FIGS. 1B and 1C, an interface 150 (symbolically illustrated using a dotted line) is present between the gate upper and lower gate structures, and in this particular example case, between the gate electrode 132a of the lower devices 102a1, 102b1 and the gate electrode 132b of the upper devices 102a2, 102b2. The interface 150 may be a seam or a grain boundary between the two gate structures. For example, as will be discussed herein later with respect to FIGS. 4, 5D1, 5D2, 5G1, and 5G2, the gate structure that includes gate electrode 132a is formed using a first gate electrode formation process (see FIGS. 5D1 and 5D2), and the gate structure that includes gate electrode 132b is formed using a second gate electrode formation process (see FIGS. 5G1 and that occurs separately from the first gate electrode formation process, thereby resulting in the interface 150 (e.g., seam or grain boundary) between the gate structures.

In the examples illustrated in FIGS. 1B and 1C, a horizontal width of the nanoribbons 118a1 is different from a width of the nanoribbons 118b1, although in other examples the nanoribbons 118a1 and 118b1 may have substantially the same width, where the width is measured in a horizontal direction that is perpendicular to a length of the nanoribbons. For example, as illustrated in FIG. 1B, a width of the nanoribbons 118a1 is aw, and a width of the nanoribbons 118b1 is bw, where in an example, aw is greater than bw. For example, aw may be greater than bw by at least 2 nm, or 4 nm, or 6 nm, or 8 nm, or 10 nm. In an example, the interface 150 has a shape that is based at least in part on the widths aw and bw. For example, the interface 150 has a first bump 150a above the nanoribbons 118a1, where the bump 150a has a width of ai, where ai is based at least in part on the width aw. For example, the first bump 150a comprises an elongated portion extending away from the nanoribbons 118a1. Similarly, the interface 150 has a second bump 150b (e.g., an elongated portion extending away from the nanoribbons 118b1) above the nanoribbons 118b1, where the bump 150b has a width of bi, where bi is based at least in part on the width bw. For example, a width of a bump is approximately proportional to, and less than, a width of the nanoribbons underneath the bump. Accordingly, as the width aw is greater than the width bw, the width ai of the bump 150a is greater than the width bi of the bump 150b. In an example, if the width of the nanoribbons of a lower device is sufficiently less, the bumps may be absent above the nanoribbons of that device. Formation of the bumps will be discussed herein later in further detail with respect to FIGS. 4, 5D1, 5D2, 5G1, and 5G2.

Note that while FIG. 1B (and some subsequent figures) show the corners of the bumps to be rectangular, the bumps may have somewhat rounded corner, e.g., as seen in a magnified view of a corner 150x of the bump 150a, see FIG. 1B.

In an example and as illustrated in FIG. 1C, a vertical distance (e.g., in Z-direction) between a top surface of a top-most nanoribbon of a lower device (e.g., a top-most of the nanoribbons 118a1 of the lower device 102a1) and a bottom surface of a partially formed bottom-most nanoribbon of a corresponding upper device (e.g., an end section of a bottom-most of the partial nanoribbons 118b1 of the upper device 102a2, see FIG. 1C) is denoted as h1. Thus, h1 is a vertical separation between nanoribbons of the lower device 102a1 and upper device 102a2. In an example, the vertical separation hl is in the range of 10-70 nm, or in the sub-range of 10-50 nm, 20-50 nm, 30-50 nm, 40-50 nm, 10-30 nm, or another appropriate subrange.

FIG. 1D illustrates a perspective view of the example semiconductor structure 100 of FIGS. 1A-1C (also referred to herein as “structure 100”) that is adjacent to another semiconductor structure 170 having a stacked device configuration including (i) lower devices 102a3 and 102b3 each having a continuous channel structure, and (ii) upper devices 102a4 and 102b4 also each having a continuous channel structure, in accordance with an embodiment of the present disclosure. Thus, FIG. 1D, the two structures 100 and 170 are adjacent to each other and separated by an isolation structure 188. The isolation structure 188 may be a gate cut, a shallow trench isolation (STI) structure, or a non-conductive wall separating the two structures 100 and 170. As discussed with respect to FIGS. 1A-1C, within the structure 100, the nanoribbons of the upper devices 102a2 and 102b2 have been depopulated or removed. In contrast, the nanoribbons 118a4 and 118b4 of the upper devices 102a4 and 102b4, respectively, of the structure 170 have not been depopulated or removed. For example, when the structure 100 is processed to selectively remove the nanoribbons of the upper devices of the structure 100, the structure 170 is masked such that the nanoribbons of the upper devices 102a4 and 102b4 of the structure 170 are not removed. Various components of the structure 170 will be apparent, based on the discussion with respect to the structure 100 in FIGS. 1A-1C.

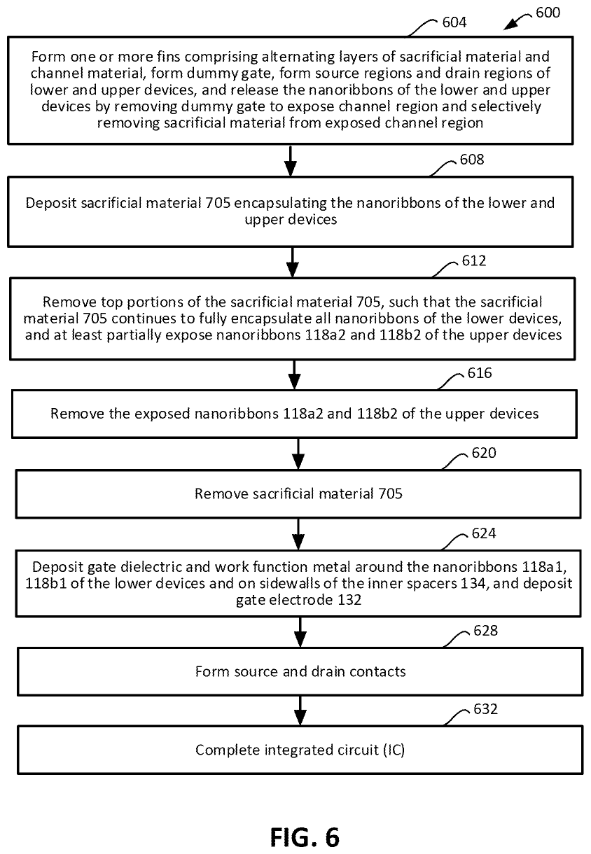

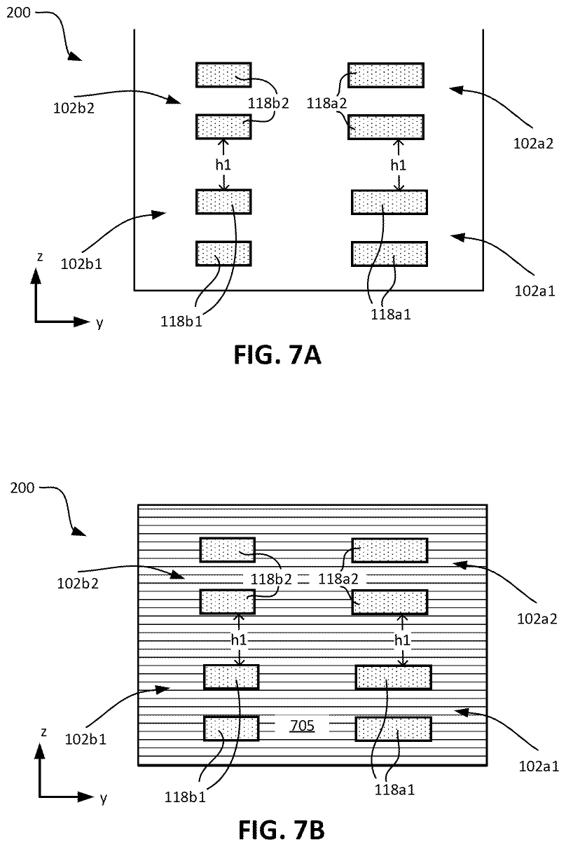

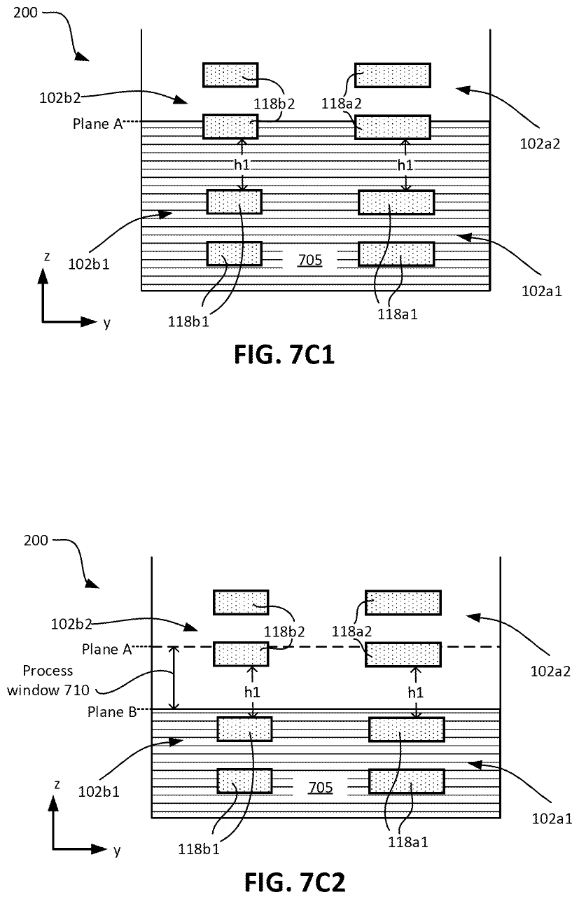

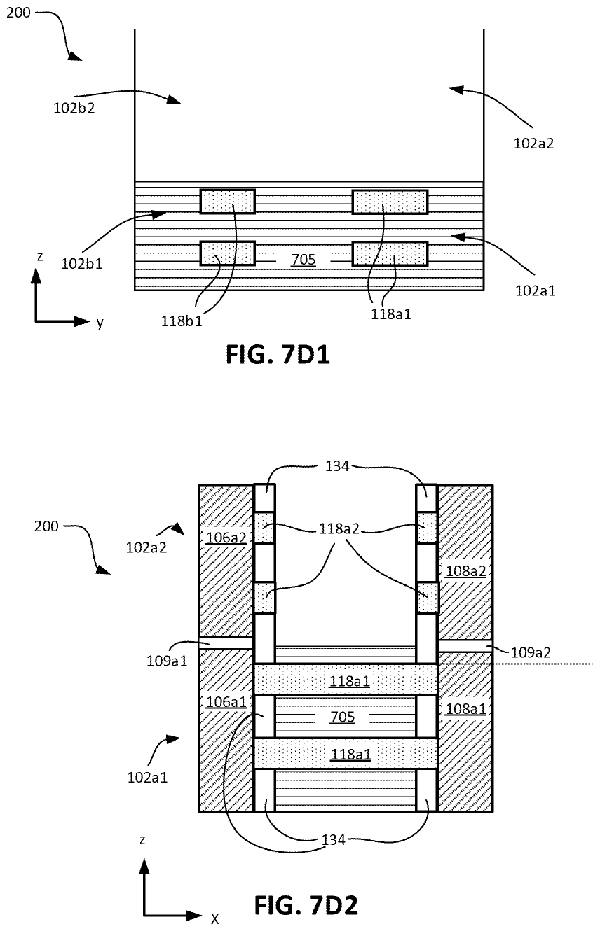

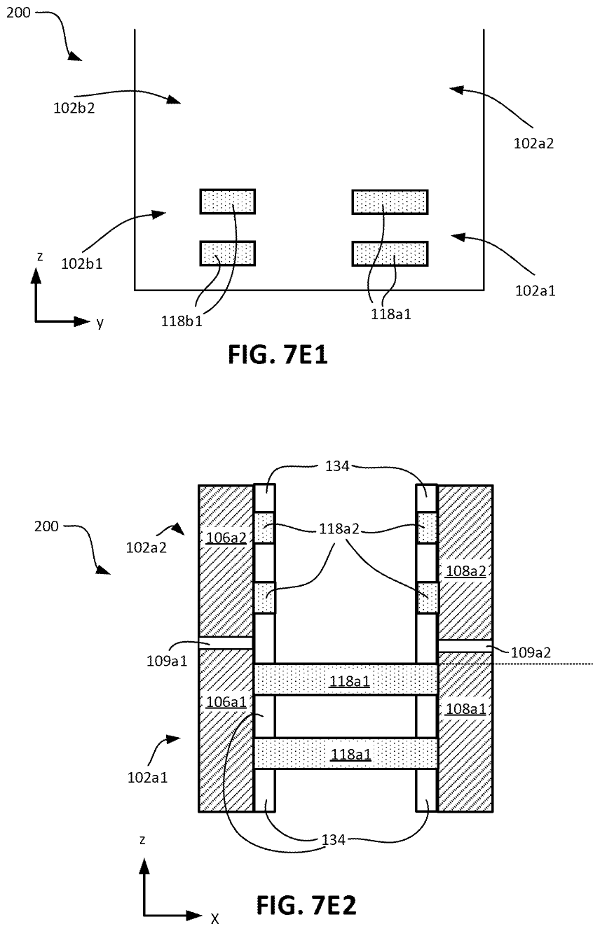

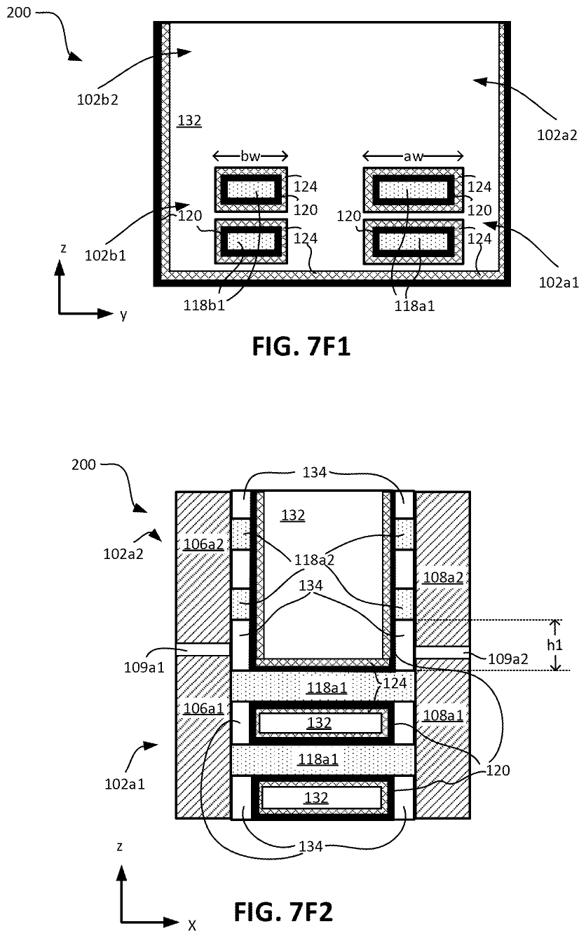

FIGS. 2A and 2B illustrate various cross-sectional views of a semiconductor structure 200 comprising a stacked device configuration including (i) lower devices 102a1 and 102b1 each having a continuous channel structure, and (ii) upper devices 102a2 and 102b2 each lacking a continuous channel structure, wherein a lower gate structure of a lower device and an upper gate structure of a upper device form a continuous common gate structure, without any interface between the lower and upper gate structures, in accordance with an embodiment of the present disclosure. The structure 200 of FIGS. 2A and 2B are respectively similar to the structure 100 of FIGS. 1B and 1C, and similar components are labelled similarly in the structures 100 and 200. However, unlike the interface 150 present between the gate structures that include electrodes 132a and 132b in the structure 100 of FIGS. 1A-1C, no such interface is present in the structure 200 of FIGS. 2A-2B. Thus, there is a single, monolithic, common and continuous gate electrode 132 for both the upper devices 102a2, 102b1 and lower devices 102a1, 102b1 in the structure 200. For example, as will be discussed herein later with respect to FIGS. 6, 7F1, and 7F2, the entire gate electrode 132 is formed during a single gate electrode formation process, and hence, no interface is present within the gate electrode 132.

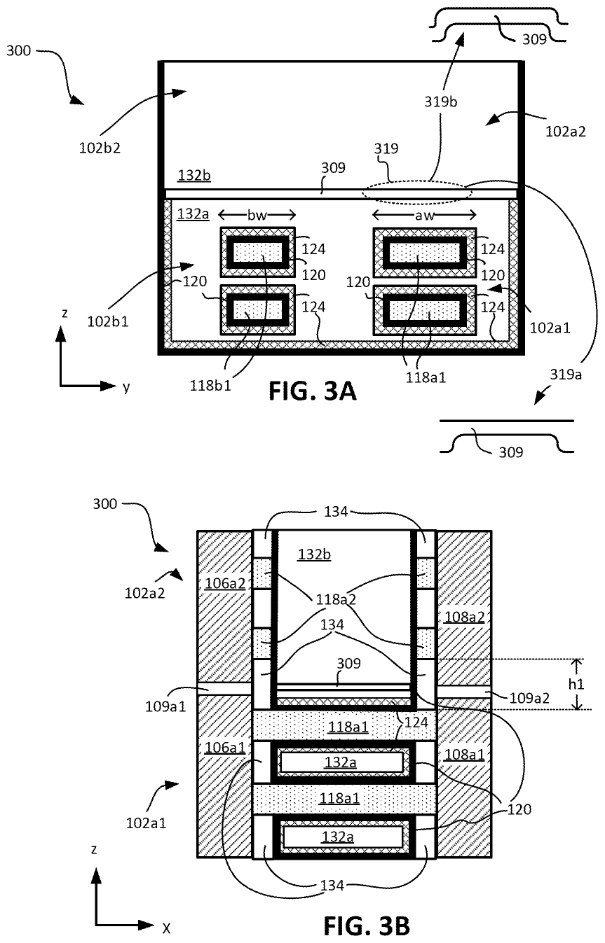

FIGS. 3A and 3B illustrate various cross-sectional views of a semiconductor structure 300 comprising a stacked device configuration including (i) lower devices 102a1 and 102b1 each having a continuous channel structure, and (ii) upper devices 102a2 and 102b2 each lacking a continuous channel structure, wherein a lower gate electrode 132a of a lower device and an upper gate electrode 132b of a corresponding upper device are separated by a non-conductive isolation region 309, in accordance with an embodiment of the present disclosure.

The structure 300 of FIGS. 3A and 3B are respectively similar to the structure 100 of FIGS. 1B and 1C, and similar components are labelled similarly in the structures 100 and 300. However, the isolation region 309 separates and electrically isolates the two gate electrodes 132a and 132b. In a case such as those depicted in FIGS. 1A-C, note that the isolation region 309 may have topology that includes bumps 150a-b. For example, two example zoomed-in views 319a and 319b of a section of the isolation region 309, which is within a dotted oval 319, is illustrated in FIG. 3A. The section of the isolation region 309 is above the nanoribbons 118a1. In the first example zoomed-in view 319a, the isolation region 309 has topology that includes a bump (e.g., having a profile similar to the bump 150a discussed herein previously). In this view 319a, only the lower surface of the isolation region 309 has the bump. In the second example zoomed-in view 319b, the isolation region 309 has topology that also includes the bump, and here both upper and lower surfaces of the isolation region 309 have the bump. Note that the section of the isolation region 309 above the nanoribbons 118b1 may also have a similar bump.

Alternatively, in a case such as those depicted in FIGS. 2A-B, note that the isolation region 309 may be a relatively smooth or flat layer.

FIG. 4 illustrates a flowchart depicting a method 400 of forming the example nanoribbon semiconductor structure 100 of FIGS. 1A-1C, in accordance with an embodiment of the present disclosure. FIGS. 5A1, 5A2, 5B1, 5B2, 5C1, 5C2, 5D1, 5D2, 5E1, 5E2, 5F1, 5F2, 5G1, and 5G2 collectively illustrate cross-sectional views of an example semiconductor structure (e.g., the semiconductor structure 100 of FIGS. 1A-1C) in various stages of processing, in accordance with an embodiment of the present disclosure. FIGS. 4 and 5A1-5G2 will be discussed in unison. The cross-sectional views of FIGS. 5A1, 5B1, 5C1, 5D1, 5E1, 5F1, and 5G1 correspond to the cross-sectional view of FIG. 1B, and the cross-sectional views of FIGS. 5A2, 5B2, 5C2, 5D2, 5E2, 5F2 and 5G2 correspond to the cross-sectional view of FIG. 1C.

Referring to FIG. 4, the method 400 includes, at 404, forming one or more fins comprising alternating layers of sacrificial material and channel material of one or more upper devices (e.g., devices 102a2, 102b2) and one or more lower devices (e.g., devices 102a1, 102b1), forming dummy gate, forming source regions and drain regions of lower and upper devices (e.g., source regions 106a1, 106a2 , and drain regions 108a1, 108a2), and releasing the nanoribbons (e.g., nanoribbons 118a1 of device 102a1, nanoribbons 118a2 of device 102a2, nanoribbons 118b1 of device 102b1, and nanoribbons 118b2 of device 102b2) of the lower and upper devices by removing the dummy gate to expose the channel region and then selectively removing sacrificial material from exposed channel region. The final structure subsequent to process 404 is illustrated in the cross-sectional view of FIGS. 5A1 and 5A2. The process 404 may include any appropriate techniques for forming nanoribbons of a stacked GAA device architecture having a lower device, and an upper device stacked above the lower device. As discussed herein previously, the upper devices are one of PMOS or NMOS devices, and the lower devices are another of PMOS or NMOS devices.

Referring again to FIG. 4, the method 400 then proceeds from 404 to 408, where gate dielectric material 120 and optionally work function metal 124 are deposited around the nanoribbons 118a1, 118b1, 118a2, and 118b2 of the lower and upper devices, e.g., as illustrated in FIGS. 5B1 and 5B2.

Referring again to FIG. 4, the method 400 then proceeds from 408 to 412, where gate electrode 532 is deposited on the structure 100, where the gate electrode 532 encapsulates at least the nanoribbons 118a1, 118b1 of the lower devices 102a1, 102b2, respectively, and optionally one or more nanoribbons 118a1, 118b2 of the upper devices 102a2, 102b2, respectively. For example, FIGS. 5C1 and 5C2 illustrate the gate electrode 532 encapsulating all the nanoribbons 118. In an example, the gate electrode 532 is deposited using an appropriate deposition technique, such as chemical vapor deposition (CVD), physical vapor deposition (PVD), atomic layer deposition (ALD), vapor-phase epitaxy (VPE), molecular beam epitaxy (MBE), or liquid-phase epitaxy (LPE), for example. In an example, the gate electrode 532 may include any sufficiently conductive material, such as a metal, metal alloy, or doped polysilicon.

Referring again to FIG. 4, the method 400 then proceeds from 412 to 416, where top portions of the gate electrode is removed, such that the gate electrode continues to fully encapsulate all nanoribbons of the lower devices, and does not encapsulate any nanoribbon of the upper devices. For example, FIGS. 5D1 and 5D2 illustrate the recessed gate electrode 532, which is now also referred to as gate electrode 132a that encapsulates the nanoribbons 118a1 and 118b1 of the lower devices 102a1 and 102b1, respectively. The removal of the top portions of the gate electrode generates unfiled portions 550, as illustrated in FIGS. 5D1 and 5D2.

In an example, the top portions of the gate electrode 532 is removed using an appropriate etch process, e.g., an isotropic etch process. Note that because of the relatively small vertical gap (e.g., in the range of 10-50 nm, or a subrange therewithin, as discussed herein previously) between the nanoribbons of the upper devices and the lower devices and because of unintended technical limitations in the etch process, the top surface of the recessed gate electrode 132a may not be smooth or planar. Rather, bumps 550a and 550b may be formed underneath the nanoribbons 118a2 and 118b2, respectively, as illustrated in Fig. SD 1. For example, the gate electrode material within the bumps 550a, 550b may not be fully removed by the etch process, due to a shadowing effect of the nanoribbons 118a1, 118b2 over the bumps. The bumps 550a and 550b are peaks or elongated portions that protrudes upwards towards the upper devices. Their shape may be less boxy in other embodiments. For instance, in another embodiment bumps 550a, 550b may have inwardly-tapered sidewalls and rounded corners, e.g., as illustrated in a magnified view of an example corner 550x of the bump 550a. In still another embodiment, bump 550b may be a shorter or otherwise lesser bump (or even no bump) as compared to bump 550a, depending on factors such as the distance hl between the top surface of the uppermost nanoribbon 118b1 and the bottom surface of the lowermost nanoribbon 118b2, as well as the exposed lateral width w1 (see FIG. 5A1) and length l1 (see FIG. 5A2) of the lowermost nanoribbon 118b2. Such dimensions effectively define the aspect ratio of the space between the upper and lower nanoribbons, and thus further define the ability of the etch process that removes the upper gate structure to access that space. In some cases, for instance, an isotropic gate recess etch process may actually completely remove bump 550b but leave at least some portion of bump 550a.

Referring again to FIG. 4, the method 400 then proceeds from 416 to 420, where the work function metal 124 and gate dielectric 120 are removed from the exposed nanoribbons 118a2 and 118b2 of the upper devices, e.g., as illustrated in FIGS. 5E1 and 5E2. The work function metal 124 and gate dielectric 120 are removed using an appropriate etch process, e.g., an isotropic etch process which is selective to the material of the gate electrode 132a. For example, the etch process (or processes, as the case may be) removes the work function metal 124 and gate dielectric 120 from the nanoribbons 118a2 and 118b2 of the upper devices, without substantially removing the gate electrode 132a. The work function metal 124 and gate dielectric 120 around nanoribbons 118a1 and 118b1 of the lower devices are protected by the gate electrode 132a, and hence, and not removed. In an example, a first removal process may remove the work function metal 124 and a second removal process may remove the gate dielectric 120, although in another example the first and second removal processes may be at least in part combined in a single common removal process.

Referring again to FIG. 4, the method 400 then proceeds from 420 to 424, where the exposed nanoribbons 118a2 and 118b2 of the upper devices are removed, e.g., as illustrated in FIGS. 5F1 and 5F2.

The nanoribbons 118a2 and 118b2 of the upper devices are removed using an appropriate etch process, e.g., an isotropic etch process which is selective to the material of the gate electrode 132a. For example, the etch process removes the nanoribbons 118a2 and 118b2 of the upper devices, without substantially etching the gate electrode 132a.

Note that in an example, the middle section of the nanoribbons 118a2, 118b2 are removed, and end sections of the nanoribbons 118a2, 118b2 are protected by the inner gate spacers 134 and hence, not removed, as illustrated in FIG. 5F2. Thus, the partial removal of the nanoribbons 118a2, 118b2 form discontinuous nanoribbons in the upper devices, where a discontinuous nanoribbon (e.g., discontinuous nanoribbon 118a2) has two end sections protected by the inner gate spacers 134 and lacks a middle portion joining the two end sections.

Referring again to FIG. 4, the method 400 then proceeds from 424 to 428, where gate dielectric material is deposited on walls of the inner spacers 134 of the upper devices. A conformal deposition technique can be used, such as ALD or CVD. In this example, note that gate dielectric material deposited on top of gate electrode 132b (and other exposed lateral surfaces) can be removed with a directional etch, leaving the gate dielectric material only on the sidewalls as shown in FIGS. 1B-C. As can be further seen in this example, the gate electrode 132b of the upper devices is deposited above the gate electrode 132a of the lower devices, e.g., as illustrated in FIGS. 5G1 and 5G2. The gate electrode 132b can be deposited using an appropriate deposition technique, such as CVD, PVD, ALD, VPE, MBE, or LPE, for example. Note that because the gate electrode 132a of the lower devices and the gate electrode 132b of the upper devices are formed by two different processes (e.g., processes 412 and 428, respectively), the interface 150 is formed between the lower and upper gate structures that include gate electrodes 132a and 132b, respectively as also discussed herein previously and as illustrated in FIGS. 5G1 and 5G2. So, in such an example, note that the gate dielectric material 120 (and not the work function metal 124) is deposited on the sidewalls of the inner spacers 134 for the upper devices 102a1, 102b2. Accordingly, for the lower devices 102a1, 102b1, both gate dielectric material 120 and work function metal 124 separate the gate electrode 132a from the inner spacers 134, as illustrated in FIG. 5G1. In contrast, for the upper devices 102a2, 102b2, only gate dielectric material 120 (and not work function metal 124) separates the gate electrode 132b from the inner spacers 134, as illustrated in FIG. 5G1. In some other examples, a work function metal is deposited prior to the gate electrode 132b or is otherwise included in electrode 132b. Such an embodiment may be helpful, for instance, where at least some other upper channel regions (e.g., to the left and/or right of the depicted channel regions) are not depopulated and have their corresponding gate regions subjected to a final gate process to form fully functional channel regions that have a gate-all-around structure. In such cases, it may ease processing complexity to treat the depopulated upper channel regions the same as the populated channel regions, rather than have a different process. So, for instance, even though a given depopulated upper channel region has no nanoribbons, the various gate materials are deposited into that corresponding upper gate trench. Further note that the upper and lower work function materials may be different, such as p-type work function on the lower gate structures and n-type work function on the upper gate structures (or vice-versa). In still other cases, there may be a dielectric isolation structure between upper and lower gate structures (if circuit calls for isolated gates). In such a case, note that the non-conductive isolation region may have topology that includes bumps 150a-b.

The method 400 of FIG. 4 then proceeds from 428 to 432, where source and drain contacts are formed (not illustrated), which couples the various source and drain regions to one or more metallization levels. In some embodiments, the source and drain contacts can be formed using any suitable techniques, such as forming contact trenches in an ILD layer adjacent to the respective source and drain regions, and then depositing metal or metal alloy (or other suitable electrically conductive material) in the trenches. In some embodiments, forming the source and drain contacts may include silicidation, germanidation, III-V-idation, and/or annealing processes, for example.

The method 400 of FIG. 4 then proceeds from 432 to 436, where a general integrated circuit (IC) is completed, as desired, in accordance with some embodiments. Such additional processing to complete an IC may include back-end or back-end-of-line (BEOL) processing to form one or more metallization layers and/or to interconnect the transistor devices formed, for example. Any other suitable processing may be performed, as will be apparent in light of this disclosure.

Note that the processes in method 400 are shown in a particular order for ease of description. However, one or more of the processes may be performed in a different order or may not be performed at all (and thus be optional), in accordance with some embodiments. Numerous variations on method 400 and the techniques described herein will be apparent in light of this disclosure.

FIG. 6 illustrates a flowchart depicting a method 600 of forming the example nanoribbon semiconductor structure 200 of FIGS. 2A-2B, in accordance with an embodiment of the present disclosure. FIGS. 7A, 7B, 7C1, 7C2, 7D1, 7D2, 7E1, 7E2, 7F1, and 7F2 collectively illustrate cross-sectional views of an example semiconductor structure (e.g., the semiconductor structure 200 of FIGS. 2A-2B) in various stages of processing, in accordance with an embodiment of the present disclosure. FIGS. 6 and 7A-7F2 will be discussed in unison.

Referring to FIG. 6, the method 600 includes, at 604, forming one or more fins comprising alternating layers of sacrificial material and channel material of one or more upper devices (e.g., devices 102a2, 102b2) and one or more lower devices (e.g., devices 102a1, 102b1), forming dummy gate, forming source regions and drain regions of lower and upper devices (e.g., source regions 106a1, 106a2 , and drain regions 108a1, 108a2), and releasing the nanoribbons (e.g., nanoribbons 118a1 of device 102a1, nanoribbons 118a2 of device 102a2, nanoribbons 118b1 of device 102b1, and nanoribbons 118b2 of device 102b2) of the lower and upper devices by removing the dummy gate to expose the channel region and then selectively removing sacrificial material from exposed channel region. The final structure subsequent to process 604 is illustrated in the cross-sectional view of FIG. 7A, which is similar to the previously discussed FIG. 5A. The process 604 may include any appropriate techniques for forming nanoribbons of a stacked GAA device architecture having a lower device, and an upper device stacked above the lower device. As discussed herein previously, the upper devices are one of PMOS or NMOS devices, and the lower devices are another of PMOS or NMOS devices.

Referring again to FIG. 6, the method 600 then proceeds from 604 to 608, where sacrificial material 705 encapsulating the nanoribbons of the lower and upper devices is deposited, as illustrated in FIG. 7B. In an example, the sacrificial material 705 is etch selective to the material of the nanoribbons 118a2 and 118b2 of the upper devices. For example, an etch process that etches the nanoribbons 118a2 and 118b2 of the upper devices may not substantially etch the sacrificial material 705.

Referring again to FIG. 6, the method 600 then proceeds from 608 to 612, where top portion of the sacrificial material 705 is removed, such that the sacrificial material 705 continues to fully encapsulate all nanoribbons of the lower devices, and at least partially expose nanoribbons 118a2 and 118b2 of the upper devices, e.g., as illustrated in FIGS. 7C1 and 7C2. For example, in FIG. 7C1, a relatively smaller portion of the sacrificial material 705 is removed (e.g., the sacrificial material 705 is now up until a plane A), such that the top surfaces of the bottom ones of the nanoribbons 118b2 and 118a2 are exposed through the recessed sacrificial material 705. In FIG. 7C2, a relatively larger portion of the sacrificial material 705 is removed (e.g., the sacrificial material 705 is now up until a plane B), such that entirety of the nanoribbons 118b2 and 118a2 are exposed, and the recessed sacrificial material 705 now barely covers the top surfaces of the top-most ones of the nanoribbons 118a1 and 118b1 of the lower devices. In an example, the removal of the sacrificial material 705 illustrated in both FIGS. 7C1 and 7C2 are acceptable, and the sacrificial material 705 may be removed such that the top surface of the sacrificial material 705 is anywhere between planes A and B, labelled as process window 710 in FIG. 7C2. In an example, a timed etch process may be employed to remove the sacrificial material, such that the top surface of the sacrificial material 705 is anywhere between planes A and B, i.e., within the process window 710.

Referring again to FIG. 6, the method 600 then proceeds from 612 to 616, where the exposed nanoribbons 118a2 and 118b2 of the upper devices are removed, e.g., etched using an isotropic etch process, as illustrated in FIGS. 7D1 and 7D2.

Similar to FIG. 5F2 and as illustrated in FIG. 7D2, in an example, the middle section of the nanoribbons 118a2, 118b2 are removed, and end sections of the nanoribbons 118a2, 118b2 are protected by the inner gate spacers 134 and hence, not removed. Thus, the partial removal of the nanoribbons 118a2, 118b2 form discontinuous nanoribbons in the upper devices, where a discontinuous nanoribbon (e.g., discontinuous nanoribbon 118a2) has two end sections protected by the inner gate spacers 134 and lacks a middle portion joining the two end sections.

Referring again to FIG. 6, the method 600 then proceeds from 616 to 620, where the sacrificial material 705 is removed, e.g., via a selective etch process that removes the sacrificial material 705, without substantially impacting the nanoribbons 118a1 and 118b1, e.g., as illustrated in FIGS. 7E1 and 7E2.

Referring again to FIG. 6, the method 600 then proceeds from 620 to 624, where gate dielectric 120 and work function metal 124 are deposited around the nanoribbons 118a1, 118b1 of the lower devices and on sidewalls of the inner spacers 134, and subsequently the gate electrode 132 is deposited, as illustrated in FIGS. 7F1 and 7F2. Because the entire gate electrode 132 is deposited through a single deposition process, no interface is formed between the gate structures of the upper and lower devices, e.g., as discussed herein earlier with respect to FIGS. 2A-2B. The gate dielectric 120 (and also the work function metal 124) separates the gate electrode 132 from the end sections of the nanoribbons 118a2, 118b2 and also from the nanoribbons 118a1, 118b1, as illustrated in FIGS. 7F1 and 7F2. In other embodiments, distinct upper and lower gate structures may be provisioned, as previously explained above, such as in the example case where a common gate process is applied to both depopulated and populated upper channel regions. In still other cases, there may be a dielectric isolation structure between upper and lower gate structures (e.g., if circuit calls for isolated gates).

The method 600 of FIG. 6 then proceeds from 624 to 628, where source and drain contacts are formed (not illustrated), which couples the various source and drain regions to one or more metallization levels. In some embodiments, the source and drain contacts can be formed using any suitable techniques, such as forming contact trenches in an ILD layer adjacent to the respective source and drain regions, and then depositing metal or metal alloy (or other suitable electrically conductive material) in the trenches. In some embodiments, forming the source and drain contacts may include silicidation, germanidation, III-V-idation, and/or annealing processes, for example.

The method 600 of FIG. 6 then proceeds from 628 to 632, where a general integrated circuit (IC) is completed, as desired, in accordance with some embodiments. Such additional processing to complete an IC may include back-end or back-end-of-line (BEOL) processing to form one or more metallization layers and/or to interconnect the transistor devices formed, for example. Any other suitable processing may be performed, as will be apparent in light of this disclosure.

Note that the processes in method 600 are shown in a particular order for ease of description. However, one or more of the processes may be performed in a different order or may not be performed at all (and thus be optional), in accordance with some embodiments. Numerous variations on method 600 and the techniques described herein will be apparent in light of this disclosure.

FIGS. 4-7F2 discusses various examples in which the gate electrode of the upper devices and the gate electrode of the lower devices are continuous (e.g., not separated by any isolation region, although the interface 150 may be optionally present), e.g., to form the structure 100 of FIGS. 1A-1C or the structure 200 of FIGS. 2A-2B. However, the methods 400 or 600 may be appropriately modified, to include an isolation region 309 between the gate structure of the upper devices and the gate structure of the lower devices. For example, subsequent to the operations discussed with respect to FIGS. 5F1 and 5F2 and prior to the operations discussed with respect to FIGS. 5G1 and 5G2, an isolation region 309 may be formed above the lower gate structure that includes gate electrode 132a, and then the upper gate structure that includes gate electrode 132b may be formed, to achieve the structure 300 of FIGS. 3A-3B. In another example, the gate structure formation operations discussed with respect to FIGS. 7F1 and 7F2 may be divided in multiple process, e.g., (i) a first process to form the gate structure that includes lower gate electrode 132a for the lower devices 102a1, 102b1, (ii) a second process to form the isolation region 309 above the lower gate structure, and (iii) a third process to form the gate structure that includes upper gate electrode 132b above the isolation region 309, to achieve the structure 300 of FIGS. 3A-3B.

### EXAMPLE SYSTEM

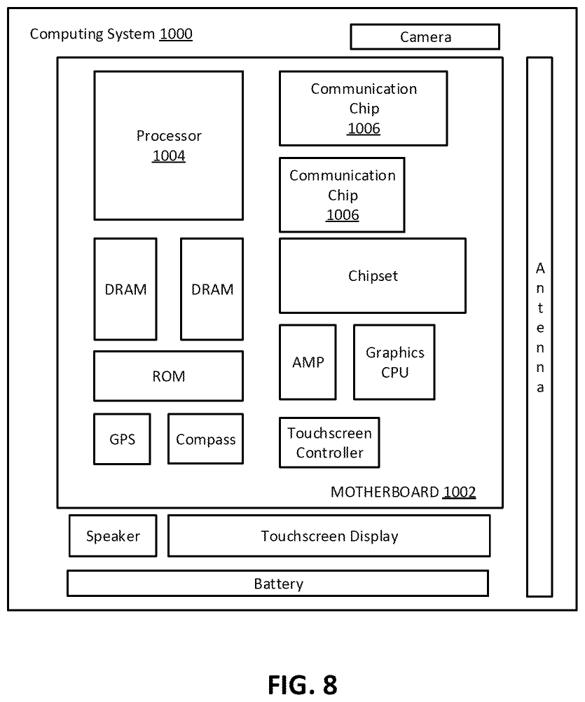

FIG. 8 illustrates a computing system 1000 implemented with integrated circuit structures and/or transistor devices formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1. A semiconductor structure comprising: a second device stacked over a first device, wherein the first device comprises (i) a first source region, (ii) a first drain region, (iii) a body of semiconductor material extending laterally from the first source region to the first drain region, and (iv) a first gate structure at least in part wrapped around the body, wherein the second device comprises (i) a second source region, (ii) a second drain region, and (iii) a second gate structure at least in part laterally between the second source region and the second drain region, and wherein the second device lacks a body of semiconductor material extending laterally from the second source region to the second drain region.

Example 2. The semiconductor structure of example 1, wherein there is an interface between the first gate structure and the second gate structure.

Example 3. The semiconductor structure of example 2, wherein: the interface between the first gate structure and the second gate structure has a non-planar profile, with an elongated section above the body and away from the body.

Example 4. The semiconductor structure of any of examples 1-3, wherein a top surface of the first gate structure includes topology including one or more upward extending portions and one or more lower portions, and a bottom surface of the second gate structure conforms to that topology.

Example 5. The semiconductor structure of example 1, comprising a non-conductive isolation structure between the first and second gate structures, wherein a top surface of the first gate structure includes topology including one or more upward extending portions and one or more lower portions, and at least a bottom surface of the non-conductive isolation structure conforms to that topology.

Example 6. The semiconductor structure of example 1, wherein the first gate structure includes a first gate electrode and the second gate structure includes a second gate electrode, with a layer of non-conductive material between the first gate electrode and the second gate electrode.

Example 7. The semiconductor structure of example 1, wherein the first gate structure includes a first gate electrode and the second gate structure includes a second gate electrode, and wherein the first gate electrode and the second gate electrode form a continuous gate electrode structure, without any interface or intervening layer between the first gate electrode and the second gate electrode.

Example 8. The semiconductor structure of any of examples 1-7, wherein the body is a first body, and wherein the second device comprises a discontinuous second body comprising (i) a first end section in contact with the second source region, and (ii) a second end section in contact with the second drain region, the second body lacking a middle region between the first end section and the second end section.

Example 9. The semiconductor structure of example 8, wherein the second gate structure includes (i) a gate electrode, and (ii) gate dielectric material that is between the gate electrode and the first end section of the second body, and that is also between the gate electrode and the second end section of the second body.

Example 10. The semiconductor structure of any of examples 8-9, further comprising: a gate spacer separating the first gate structure from the first source region, and separating the second gate structure from the second source region, wherein the first end section of the second body is at least in part wrapped around by the gate spacer.

Example 11. The semiconductor structure of example 10, wherein the gate spacer is a first gate spacer, and wherein the semiconductor structure further comprises: a second gate spacer separating the first gate structure from the first drain region, and separating the second gate structure from the second drain region, wherein the second end section of the second body is at least in part wrapped around by the second gate spacer.

Example 12. The semiconductor structure of any of examples 8-11, wherein the first end section and the second end section of the second body are coplanar.

Example 13. The semiconductor structure of any of examples 1-12, wherein the body is a first body, and wherein the first device further comprises: a second body comprising the semiconductor material extending laterally between the first source region and the first drain region, wherein the first body and the second body are included in a vertical stack including two or more nanowires, nanoribbons, or nanosheets.

Example 14. The semiconductor structure of any of examples 1-13, wherein the first device is one of an n-channel metal-oxide semiconductor (NMOS) device or a p-channel metal-oxide semiconductor (PMOS) device, and the second device is the other of an NMOS device or a PMOS device.

Example 15. The semiconductor structure of any of examples 1-14, comprising: a third device stacked over a fourth device, wherein the third device comprises (i) a third source region, (ii) a third drain region, (iii) a body of semiconductor material extending laterally from the third source region to the third drain region, and (iv) a third gate structure at least in part wrapped around the body of semiconductor material extending laterally from the third source region to the third drain region, and wherein the fourth device comprises (i) a fourth source region, (ii) a fourth drain region, (iii) a body of semiconductor material extending laterally from the fourth source region to the fourth drain region, and (iv) a fourth gate structure at least in part wrapped around the body of semiconductor material extending laterally from the fourth source region to the fourth drain region.

Example 16. The semiconductor structure of any of examples 1-15, wherein the body of semiconductor material extending laterally from the first source region to the first drain region is a nanoribbon, around which the first gate structure is wrapped.

Example 17. The semiconductor structure of any of examples 1-16, wherein the body of semiconductor material extending laterally from the first source region to the first drain region is a fin, around which the first gate structure is at least partially wrapped.

Example 18. An integrated circuit structure comprising: a source region; a drain region; a gate electrode at least in part laterally between the source region and the drain region; a first spacer laterally between the gate electrode and the source region, and a second spacer laterally between the gate electrode and the drain region; a first body comprising semiconductor material at least in part wrapped by the first spacer and is contact with the source region; and a second body comprising semiconductor material at least in part wrapped by the second spacer and is contact with the drain region, wherein the first body and the second body are coplanar and separated by the gate electrode.

Example 19. The integrated circuit structure of example 18, further comprising: gate dielectric material between the first body and the gate electrode, and between the second body and the gate electrode.

Example 20. The integrated circuit structure of example 19, wherein a first end of the first body is in contact with the source region and an opposite second end of the first body is in contact with the gate dielectric, and no section of the first body is in contact with the drain region.

Example 21. The integrated circuit structure of any of examples 19-20, wherein a first end of the second body is in contact with the drain region and an opposite second end of the second body is in contact with the gate dielectric, and no section of the second body is in contact with the source region.

Example 22. The integrated circuit structure of any of examples 18-21, wherein no section of the first body is in contact with the drain region, and no section of the second body is in contact with the source region.

Example 23. The integrated circuit structure of any of examples 18-22, wherein the source region is a first source region, the drain region is a first drain region, the gate electrode is a first gate electrode, and wherein the integrated circuit structure comprises: a second source region below the first source region, and separated from the first source region by a first non-conductive material; a second drain region below the first drain region, and separated from the first drain region by a second non-conductive material; a third body laterally between and in contact with the second source region and the second drain region; and a second gate electrode at least in part laterally between the second source region and the second drain region, the second gate electrode at least in part wrapping the third body.

Example 24. The integrated circuit structure of example 23, wherein: a first end section of the third body is at least in part wrapped by the first spacer and is contact with the source region; and a second end section of the third body is at least in part wrapped by the second spacer and is contact with the drain region.

Example 25. The integrated circuit structure of any of examples 23-23, wherein the first gate electrode is in contact with the second gate electrode, with an interface between the first gate electrode and the second gate electrode.

Example 26. The integrated circuit structure of example 25, wherein the interface between the first gate electrode and the second gate electrode has a non-planar structure, with an elongated section above the third body, the elongated section elongated away from the third body.

Example 27. The integrated circuit structure of example 23, further comprising a layer of non-conductive material between the first gate electrode and the second gate electrode.

Example 28. The integrated circuit structure of example 23, wherein the first gate electrode and the second gate electrode form a continuous gate electrode structure, without any interface or intervening layer between the first gate electrode and the second gate electrode.

Example 29. A method comprising: forming a second device stacked vertically over a first device, the first device comprising a first body laterally between and in contact with a first source region and a first drain region, and the second device comprising a second body laterally between and in contact with a second source region and a second drain region, wherein the second body comprises (i) a first end section wrapped at least in part by a first spacer, (ii) a second end section wrapped at least in part by a second spacer, and (iii) a central section laterally between the first and second end sections; and removing the central section of the second body, without removing the first and second end sections of the second body and without removing the first body.

Example 30. The method of example 29, wherein removing the central section of the second body comprises: forming a gate structure comprising (i) a gate electrode at least in part wrapping around a central section of the first body and the central section of the second body, and (ii) gate dielectric between the gate electrode and the central section of the first body, and between the gate electrode and the central section of the second body; removing an upper portion of the gate electrode, such that the gate electrode wraps the central section of the first body and does no wrap the central section of the second body; and removing the gate dielectric from the central section of the second body that is not wrapped by the gate electrode, and subsequently removing the central section of the second body.

Example 31. The method of example 30, wherein the gate electrode wrapping the central section of the first body is a first gate electrode, the method further comprising: subsequent to removing the central section of the second body, forming a second gate electrode above the first gate electrode, to thereby form an interface between the first and second gate electrodes.

Example 32. The method of example 30, wherein the gate electrode wrapping the central section of the first body is a first gate electrode, the method further comprising: subsequent to removing the central section of the second body, forming an isolation region comprising non-conductive material above the first gate electrode; and forming a second gate electrode above the isolation region, the isolation region between the first and second gate electrodes.

Example 33. The method of example 29, wherein removing the central section of the second body comprises: forming a layer of sacrificial material encapsulating a central section of the first body and the central section of the second body; removing an upper portion of the layer of sacrificial material, such that the layer of sacrificial material wraps the central section of the first body and does no wrap the central section of the second body; and removing the central section of the second body that is not wrapped by the layer of sacrificial material.

Example 34. The method of example 33, further comprising: removing the layer of sacrificial material; and forming a gate structure comprising (i) a gate electrode at least in part wrapping around the central section of the first body, and (ii) gate dielectric between the gate electrode and the central section of the first body.

Example 35. The method of any of examples 29-34, wherein the first body comprises one of a first nanoribbon, a first nanowire, or a first nanosheet, and the first end and the second end of the second body comprises two ends of a second nanoribbon, a second nanowire, or a second nanosheet.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. A semiconductor structure comprising:
a second device stacked over a first device,
wherein the first device comprises (i) a first source region, (ii) a first drain region, (iii) a body of semiconductor material extending laterally from the first source region to the first drain region, and (iv) a first gate structure at least in part wrapped around the body,
wherein the second device comprises (i) a second source region, (ii) a second drain region, and (iii) a second gate structure at least in part laterally between the second source region and the second drain region, and wherein the second device lacks a body of semiconductor material extending laterally from the second source region to the second drain region.

2. The semiconductor structure of claim 1, wherein there is an interface between the first gate structure and the second gate structure.

3. The semiconductor structure of claim 2, wherein:
the interface between the first gate structure and the second gate structure has a non-planar profile, with an elongated section above the body and away from the body.

4. The semiconductor structure of claim 1, wherein a top surface of the first gate structure includes topology including one or more upward extending portions and one or more lower portions, and a bottom surface of the second gate structure conforms to that topology.

5. The semiconductor structure of claim 1, comprising a non-conductive isolation structure between the first and second gate structures, wherein a top surface of the first gate structure includes topology including one or more upward extending portions and one or more lower portions, and at least a bottom surface of the non-conductive isolation structure conforms to that topology.

6. The semiconductor structure of claim 1, wherein the first gate structure includes a first gate electrode and the second gate structure includes a second gate electrode, with a layer of non-conductive material between the first gate electrode and the second gate electrode.

7. The semiconductor structure of claim 1, wherein the first gate structure includes a first gate electrode and the second gate structure includes a second gate electrode, and wherein the first gate electrode and the second gate electrode form a continuous gate electrode structure, without any interface or intervening layer between the first gate electrode and the second gate electrode.

8. The semiconductor structure of claim 1, wherein the body is a first body, and wherein the second device comprises a discontinuous second body comprising (i) a first end section in contact with the second source region, and (ii) a second end section in contact with the second drain region, the second body lacking a middle region between the first end section and the second end section.

9. The semiconductor structure of claim 8, wherein the second gate structure includes (i) a gate electrode, and (ii) gate dielectric material that is between the gate electrode and the first end section of the second body, and that is also between the gate electrode and the second end section of the second body.

10. The semiconductor structure of claim 8, further comprising:
a gate spacer separating the first gate structure from the first source region, and separating the second gate structure from the second source region,
wherein the first end section of the second body is at least in part wrapped around by the gate spacer.

11. The semiconductor structure of claim 10, wherein the gate spacer is a first gate spacer, and wherein the semiconductor structure further comprises:
a second gate spacer separating the first gate structure from the first drain region, and separating the second gate structure from the second drain region,
wherein the second end section of the second body is at least in part wrapped around by the second gate spacer.

12. The semiconductor structure of claim 8, wherein the first end section and the second end section of the second body are coplanar.

13. An integrated circuit structure comprising:
a source region;
a drain region;
a gate electrode at least in part laterally between the source region and the drain region;
a first spacer laterally between the gate electrode and the source region, and a second spacer laterally between the gate electrode and the drain region;
a first body comprising semiconductor material at least in part wrapped by the first spacer and is contact with the source region; and
a second body comprising semiconductor material at least in part wrapped by the second spacer and is contact with the drain region,
wherein the first body and the second body are coplanar and separated by the gate electrode.

14. The integrated circuit structure of claim 13, further comprising:
gate dielectric material between the first body and the gate electrode, and between the second body and the gate electrode.

15. The integrated circuit structure of claim 14, wherein a first end of the first body is in contact with the source region and an opposite second end of the first body is in contact with the gate dielectric, and no section of the first body is in contact with the drain region.

16. The integrated circuit structure of claim 14, wherein a first end of the second body is in contact with the drain region and an opposite second end of the second body is in contact with the gate dielectric, and no section of the second body is in contact with the source region.

17. The integrated circuit structure of claim 13, wherein the source region is a first source region, the drain region is a first drain region, the gate electrode is a first gate electrode, and wherein the integrated circuit structure comprises:
a second source region below the first source region, and separated from the first source region by a first non-conductive material;
a second drain region below the first drain region, and separated from the first drain region by a second non-conductive material;
a third body laterally between and in contact with the second source region and the second drain region; and
a second gate electrode at least in part laterally between the second source region and the second drain region, the second gate electrode at least in part wrapping the third body.

18. The integrated circuit structure of claim 17, wherein:
a first end section of the third body is at least in part wrapped by the first spacer and is contact with the source region; and
a second end section of the third body is at least in part wrapped by the second spacer and is contact with the drain region.

19. A method comprising:
forming a second device stacked vertically over a first device, the first device comprising a first body laterally between and in contact with a first source region and a first drain region, and the second device comprising a second body laterally between and in contact with a second source region and a second drain region, wherein the second body comprises (i) a first end section wrapped at least in part by a first spacer, (ii) a second end section wrapped at least in part by a second spacer, and (iii) a central section laterally between the first and second end sections; and
removing the central section of the second body, without removing the first and second end sections of the second body and without removing the first body.

20. The method of claim 19, wherein removing the central section of the second body comprises:
forming a gate structure comprising (i) a first gate electrode at least in part wrapping around a central section of the first body and the central section of the second body, and (ii) gate dielectric between the first gate electrode and the central section of the first body, and between the first gate electrode and the central section of the second body;
removing an upper portion of the first gate electrode, such that the first gate electrode wraps the central section of the first body and does no wrap the central section of the second body;
removing the gate dielectric from the central section of the second body that is not wrapped by the first gate electrode, and subsequently removing the central section of the second body; and
subsequent to removing the central section of the second body, forming a second gate electrode above the first gate electrode, to thereby form an interface between the first and second gate electrodes.

21. The method of claim 19, wherein removing the central section of the second body comprises:
forming a layer of sacrificial material encapsulating a central section of the first body and the central section of the second body;
removing an upper portion of the layer of sacrificial material, such that the layer of sacrificial material wraps the central section of the first body and does no wrap the central section of the second body;
removing the central section of the second body that is not wrapped by the layer of sacrificial material;
removing the layer of sacrificial material; and
forming a gate structure comprising (i) a gate electrode at least in part wrapping around the central section of the first body, and (ii) gate dielectric between the gate electrode and the central section of the first body.
